(19) United States
(12) Patent Application Publication
(10) Pub. No.: US 2013/0134534 A1
(43) Pub. Date: May 30, 2013

(54) Magnetoresistive Device

(71) Applicants: Rachid Sbiaa, Singapore (SG); Yaozhang Dean Randall Law, Singapore (SG); Seidikkurippu Nellainayagam Piramanayagam, Singapore (SG)

(72) Inventors: Rachid Sbiaa, Singapore (SG); Yaozhang Dean Randall Law, Singapore (SG); Seidikkurippu Nellainayagam Piramanayagam, Singapore (SG)

(73) Assignee: AGENCY FOR SCIENCE, TECHNOLOGY AND RESEARCH, Singapore (SG)

(21) Appl. No.: 13/695,495

(22) PCT Filed: May 4, 2011
(86) PCT No.: PCT/SG2011/000175

§ 371 Date: Feb. 14, 2013

(30) Foreign Application Priority Data
May 4, 2010 (SG) 201003157-3

(51) Int. Cl. H01L 43/02

(52) U.S. Cl. CPC H01L 43/02
USPC 257/421

(57) ABSTRACT

According to embodiments of the present invention, a magnetoresistive device having a magnetic junction is provided. The magnetic junction includes at least one fixed magnetic layer structure having a fixed magnetization orientation; and at least two free magnetic layer structures, each of the at least two free magnetic layer structures having a variable magnetization orientation; wherein the at least one fixed magnetic layer structure overlaps with the at least two free magnetic layer structures such that a current flow is possible through the magnetic junction; and wherein the at least one fixed magnetic layer structure and the at least two free magnetic layer structures are respectively configured such that the fixed magnetization orientation and the variable magnetization orientation are oriented in a direction substantially perpendicular to a plane defined by an interface between the at least one fixed magnetic layer structure and either one of the at least two free magnetic layer structures.

### CROSS-REFERENCE TO RELATED APPLICATION

This application claims the benefit of priority of Singapore patent application No. 201003157-3, filed 4 May 2010, the content of it being hereby incorporated by reference in its entirety for all purposes.

### TECHNICAL FIELD

Various embodiments relate to a magnetoresistive device having a magnetic junction.

### BACKGROUND

Until now, hard disk drive (HDD) offers an advantage of storing data at low cost. However, at the same time, other types of memories such as flash memory caught up and now represent a threat to HDD. Flash memory belongs to a category of non-volatile memories (NVM). It allows the data to be stored even when power is down or when there is no supply of power.

The flash memory market is getting bigger but the cost per gigabit (Gbit) is higher than that of HDD. HDD technology is moving towards patterned media where bits are made by lithography process. The cost per Gbit should not be increased by more than 10% or 20% in order to remain competitive. This is one of the major challenges facing the HDD technology.

The current trend is to develop NVM beyond flash memory, which is cheaper and has a high performance. Magnetoresistive random access memory (MRAM) and phase change random access memory (PC-RAM) represent good candidates for future NVM. It is expected that MRAM could be used for 5 nm cell size, which is not possible for flash memory.

For MRAM, reducing the writing current is presently under intensive investigation and development. Even though the cell size can be made smaller, the high writing current requires a relatively large transistor and thus the storage density cannot be improved. There is also a continuing effort to further increase the ultimate storage density of MRAM.

### SUMMARY

According to an embodiment, a magnetoresistive device having a magnetic junction is provided. The magnetic junction may include at least one fixed magnetic layer structure having a fixed magnetization orientation; and at least two free magnetic layer structures, each of the at least two free magnetic layer structures having a variable magnetization orientation; wherein the at least one fixed magnetic layer structure overlaps with the at least two free magnetic layer structures such that a current flow is possible through the magnetic junction; and wherein the at least one fixed magnetic layer structure and the at least two free magnetic layer structures are respectively configured such that the fixed magnetization orientation and the variable magnetization orientation are oriented in a direction substantially perpendicular to a plane defined by an interface between the at least one fixed magnetic layer structure and either one of the at least two free magnetic layer structures.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A shows a schematic block diagram of a magnetoresistive device having a magnetic junction, according to various embodiments.

FIG. 1B shows a schematic block diagram of the magnetoresistive device of the embodiment of FIG. 1A.

FIGS. 2A to 2C show schematic cross-sectional diagrams of a magnetoresistive device having a magnetic junction, according to various embodiments.

FIGS. 3A to 3C show schematic cross-sectional diagrams of a magnetoresistive device having a magnetic junction, according to various embodiments.

FIG. 4 shows a schematic cross-sectional diagram of a magnetoresistive device having a magnetic junction including spin filtering layers, according to various embodiments.

FIGS. 5A to 5C show schematic cross-sectional diagrams of a magnetoresistive device having a magnetic junction including in-plane spin polarizer layers, according to various embodiments.

FIGS. 6A to 6E show schematic cross-sectional diagrams of a magnetoresistive device having a magnetic junction, according to various embodiments.

FIGS. 7A to 7E show schematic cross-sectional diagrams of a magnetoresistive device having a magnetic junction, according to various embodiments.

FIG. 8 shows a schematic cross-sectional diagram of a magnetoresistive device having a magnetic junction including spin filtering layers, according to various embodiments.

FIG. 9 shows a plot illustrating a hysteresis loop of a magnetoresistive device having a magnetic junction with D-PSV, according to various embodiments.

FIG. 10 shows a plot illustrating resistance as a function of electrical current of a magnetoresistive device having a magnetic junction with D-PSV, according to various embodiments.

FIG. 11 shows a schematic cross-sectional diagram of a magnetoresistive device having a magnetic junction including antiferromagnetically coupled in-plane spin polarizer layers, according to various embodiments.

FIG. 12 shows a plot illustrating resistance as a function of voltage for the magnetoresistive device of the embodiment of FIG. 11.

FIG. 13 shows a schematic diagram illustrating four possible resistance states for a magnetoresistive device having a magnetic junction, according to various embodiments.

FIG. 14 shows a schematic diagram illustrating a writing scheme for achieving resistance state (1) of the embodiment of FIG. 13.

FIG. 15 shows a schematic diagram illustrating a writing scheme for achieving resistance state (2) of the embodiment of FIG. 13.

FIG. 16 shows a schematic diagram illustrating a writing scheme for achieving resistance state (3) of the embodiment of FIG. 13.

FIG. 17 shows a schematic diagram illustrating a writing scheme for achieving resistance state (4) of the embodiment of FIG. 13.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Various embodiments provide a magnetoresistive device having a magnetic junction, without or with reducing at least some of the associated disadvantages of conventional devices. The magnetoresistive device may be a magnetic memory element in a non-volatile magnetic memory device, for example a magnetic random access memory or a magnetoresistive random access memory (MRAM) device. The magnetoresistive device may be capable of higher storage density, for example, by employing multi-state storage at a lower writing current.

Various embodiments may provide a multi-bit per cell magnetoresistive device (e.g. a magnetic memory element) with perpendicular magnetization and spin torque switching.

Various embodiments may provide a magnetoresistive device (e.g. a magnetic memory element) having a magnetic junction. The magnetoresistive device may be a giant magnetoresistive (GMR) device or a tunnel magnetoresistive (TMR) device. In various embodiments, the magnetic junction may include one of a dual pseudo-spin valve (D-PSV) or a triple pseudo-spin valve (T-PSV). In a tunnel magnetoresistive (TMR) device, a magnetic junction including a D-PSV has dual tunnel junctions while a magnetic junction including a T-PSV has triple tunnel junctions.

In various embodiments, the magnetoresistive device may be a giant magnetoresistive (GMR) device or a tunnel magnetoresistive (TMR) device, with a D-PSV or a T-PSV, with a current flowing perpendicular to the plane (CPP)-direction.

Various embodiments may provide a magnetoresistive device that may enable switching magnetization by a spin torque effect in perpendicular anisotropy for a magnetic junction with a D-PSV or a T-PSV, and a method for switching magnetization by the spin torque effect. The spin torque effect enables the magnetization orientation, for example of a magnetic layer, in the D-PSV or the T-PSV, to be switched by using a spin-polarized current or a spin transfer current.

In the context of various embodiments, a magnetic junction having a dual pseudo-spin valve (D-PSV) may include a ferromagnetically hard layer (or a fixed magnetic layer structure having a fixed magnetization orientation) as a reference layer, and two ferromagnetically soft layers (or free magnetic layer structures having a varying magnetization orientation) as storage layers. The ferromagnetic layers may have their magnetic easy axis in a perpendicular direction (i.e. perpendicular anisotropy), for example in a direction substantially perpendicular to a plane defined by an interface, for example an interface between the ferromagnetically hard layer and one of the two ferromagnetically soft layers. A magnetoresistive device, for example a magnetic memory element, including a magnetic junction having a D-PSV, may have one, or two, or three, or four resistance states.

In the context of various embodiments, a magnetic junction having a triple pseudo-spin valve (T-PSV) may include at least one ferromagnetically hard layer (or a fixed magnetic layer structure having a fixed magnetization orientation) as a reference layer, and three ferromagnetically soft layers (or free magnetic layer structures having a varying magnetization orientation) as storage layers. The ferromagnetic layers may have their magnetic easy axis in a perpendicular direction (i.e. perpendicular anisotropy), for example in a direction substantially perpendicular to a plane defined by an interface, for example an interface between the at least one ferromagnetically hard layer and one of the three ferromagnetically soft layers. A magnetoresistive device, for example a magnetic memory element, including a magnetic junction having a T-PSV, may have one, or two, or three, or four, or five, or six, or seven, or eight resistance states.

In the context of various embodiments, the term “fixed magnetic layer structure” may mean a magnetic layer structure having a fixed magnetization orientation. The fixed magnetic layer structure may include a hard ferromagnetic material. The hard ferromagnetic material may be resistant to magnetization and demagnetization (i.e. not easily magnetized and demagnetized), and may have a high hysteresis loss and a high coercivity. In the context of various embodiments, a fixed magnetic layer structure may be referred to as a hard layer or a ferromagnetically hard layer.

In the context of various embodiments, the term “free magnetic layer structure” may mean a magnetic layer structure having a varying magnetization orientation. In other words, the magnetization orientation may be changed or varied, for example by applying a current, such as a spin-polarized current. The free magnetic layer structure may include a soft ferromagnetic material. The soft ferromagnetic material may be receptive to magnetization and demagnetization (i.e. easily magnetized and demagnetized), and may have a small hysteresis loss and a low coercivity. In the context of various embodiments, a free magnetic layer structure may be referred to as a soft layer or a ferromagnetically soft layer.

In various embodiments, the magnetization orientation of the free magnetic layer structure may be in one of two directions. The direction of the magnetization orientation of the free magnetic layer structure may be parallel to the magnetization orientation of the fixed magnetic layer structure, such that the two magnetization orientations are in the same direction. In the alternative, the direction of the magnetization orientation of the free magnetic layer structure may be anti-parallel to the magnetization orientation of the fixed magnetic layer structure, such that the two magnetization orientations are in opposite directions.

In the context of various embodiments, the term “easy axis” as applied to magnetism may mean an energetically favorable direction of spontaneous magnetization as a result of magnetic anisotropy. The magnetization orientation may be either of two opposite directions along the easy axis.

In various embodiments, the magnetic anisotropy of each ferromagnetic layer may be controlled over a wide range and may be well-separated without using any anti-ferromagnetic layers, thereby resulting in a simple structure and easy manufacturing process. The resistance difference between the different resistance states may also be adjusted to be at least substantially equally spaced. The magnetic element of each ferromagnetic layer may be configured to enable switching via, for example an application of a spin transfer current alone or in combination with an external magnetic field, to assist the switching. By applying the external magnetic field, the spin torque values may be reduced compared to the case without the external magnetic field. In various embodiments, the external magnetic field may be generated, for example, through electrodes carrying a current.

Various embodiments may provide a magnetic random access memory or a magnetoresistive random access memory (MRAM) device including a magnetoresistive device of various embodiments. The MRAM device may further include one or more other components or elements, for example a transistor.

In the context of various embodiments, the term “adjacent” as applied to two layers may include an arrangement where the two layers are in contact with each other or an arrangement where the two layers are separated by a spacer layer or a separation layer.

In the context of various embodiments, a separation layer may be referred to as a spacer layer.

In order that the invention may be readily understood and put into practical effect, particular embodiments will now be described by way of examples and not limitations, and with reference to the figures.

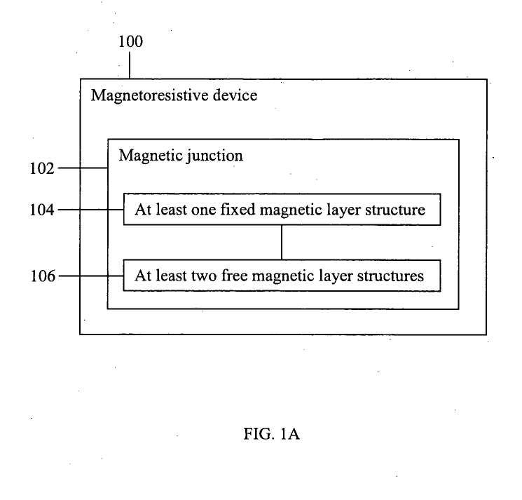

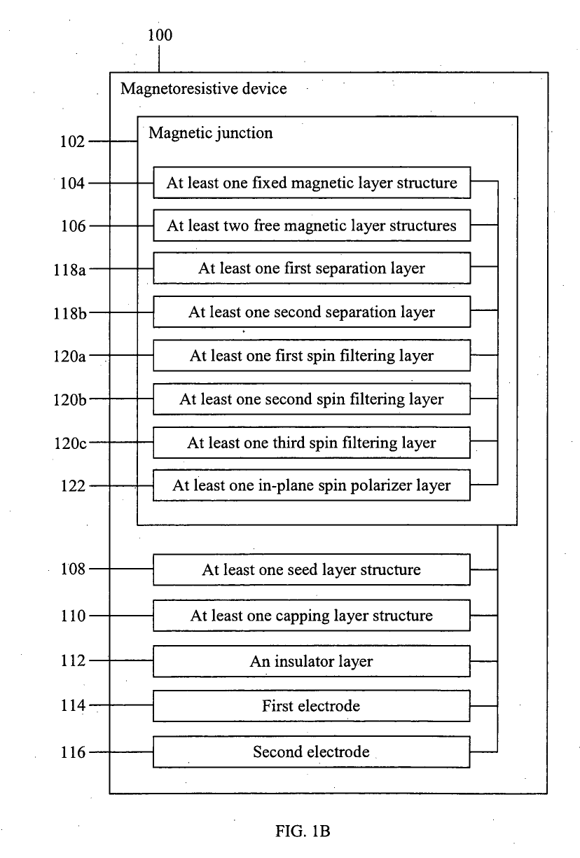

FIG. 1A shows a schematic block diagram of a magnetoresistive device 100 having a magnetic junction 102, according to various embodiments. The magnetic junction 102 includes at least one fixed magnetic layer structure 104 having a fixed magnetization orientation; and at least two free magnetic layer structures 106, each of the at least two free magnetic layer structures 106 having a variable magnetization orientation; wherein the at least one fixed magnetic layer structure 104 overlaps with the at least two free magnetic layer structures 106 such that a current flow is possible through the magnetic junction 102; and wherein the at least one fixed magnetic layer structure 104 and the at least two free magnetic layer structures 106 are respectively configured such that the fixed magnetization orientation and the variable magnetization orientation are oriented in a direction substantially perpendicular to a plane defined by an interface between the at least one fixed magnetic layer structure 104 and either one of the at least two free magnetic layer structures 106.

Each of the at least two free magnetic layer structures 106 may be configured such that the variable magnetization orientation of each of the at least two free magnetic layer structures 106 varies relative to the current applied through the magnetic junction 102.

In various embodiments, the variable magnetization orientation may include a parallel magnetization orientation or an anti-parallel magnetization orientation relative to the fixed magnetization orientation.

In various embodiments, the at least one fixed magnetic layer structure 104 may include a coercivity larger than each of the at least two free magnetic layer structures 106. The at least one fixed magnetic layer structure 104 may include a single layer or multiple layers. Each of the at least two free magnetic layer structures 106 may include a single layer or multiple layers. The at least one fixed magnetic layer structure 104 and the at least two free magnetic layer structures 106 may include a material with a perpendicular magnetic anisotropy. The at least one fixed magnetic layer structure 104 and each of the at least two free magnetic layer structures 106 may include a ferromagnetic layer.

In various embodiments, the at least one fixed magnetic layer structure 104 may be disposed between the at least two free magnetic layer structures 106, or the at least one fixed magnetic layer structure 104 may be disposed over the at least two free magnetic layer structures 106, or the at least one fixed magnetic layer structure 104 may be disposed below the at least two free magnetic layer structures 106.

FIG. 1B shows a schematic block diagram of the magnetoresistive device 100 of the embodiment of FIG. 1A. In various embodiments, the magnetoresistive device 100 may further include at least one seed layer structure 108, wherein the magnetic junction 102 may be disposed over the at least one seed layer structure 108. The at least one seed layer structure 108 may facilitate or promote the growth and/or quality of the subsequently deposited layers.

The magnetoresistive device 100 may further include at least one capping layer structure 110, wherein the at least one capping layer structure 110 may be disposed over the magnetic junction 102. The at least one capping layer structure 110 is provided to cap or enclose the magnetic junction 102. The at least one capping layer structure 110 may include a single layer or multiple layers.

The magnetoresistive device 100 may further include an insulator layer 112 configured to surround the magnetic junction 102.

The magnetoresistive device 100 may further include a first electrode 114 disposed at one side of the magnetic junction 102. The magnetoresistive device 100 may further include a second electrode 116 disposed at an opposite side of the magnetic junction 102. The first electrode 114 and the second electrode 116 may include a same or a different material. The first electrode 114 and the second electrode 116 may allow an electrical current to flow perpendicularly through the layers of the magnetic junction 102.

In various embodiments, the magnetic junction 102 may further include at least one first separation layer 118a disposed between the at least one fixed magnetic layer structure 104 and either one of the at least two free magnetic layer structures 106.

The magnetic junction 102 may further include at least one first spin filtering layer 120a disposed between the at least one fixed magnetic layer structure 104 and the at least one first separation layer 118a. The magnetic junction 102 may further include at least one second spin filtering layer 120b disposed between either one of the at least two free magnetic layer structures 106 and the at least one first separation layer 118a.

The magnetic junction 102 may further include at least one second separation layer 118b disposed between each of the at least two free magnetic layer structures 106.

The at least one first separation layer 118a and the at least one second separation layer 118b may include a same or a different material.

The magnetic junction 102 may further include at least one third spin filtering layer 120c disposed between either one of the at least two free magnetic layer structures 106 and the at least one second separation layer 118b.

The magnetic junction 102 may further include at least one in-plane spin polarizer layer 122 disposed adjacent to at least either one or both of the at least two free magnetic layer structures 106. The at least one in-plane spin polarizer layer 122 may include a magnetization orientation in a direction substantially parallel to the plane defined by the interface between the at least one fixed magnetic layer structure 104 and either one of the at least two free magnetic layer structures 106.

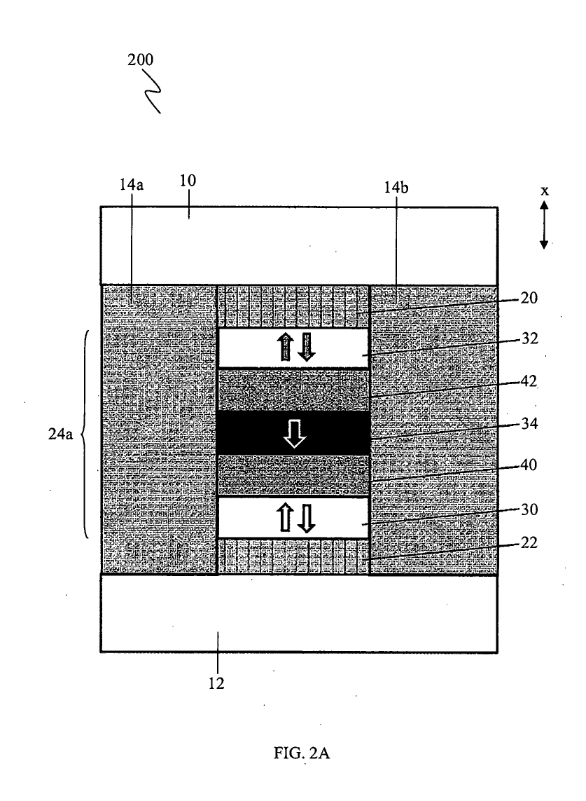

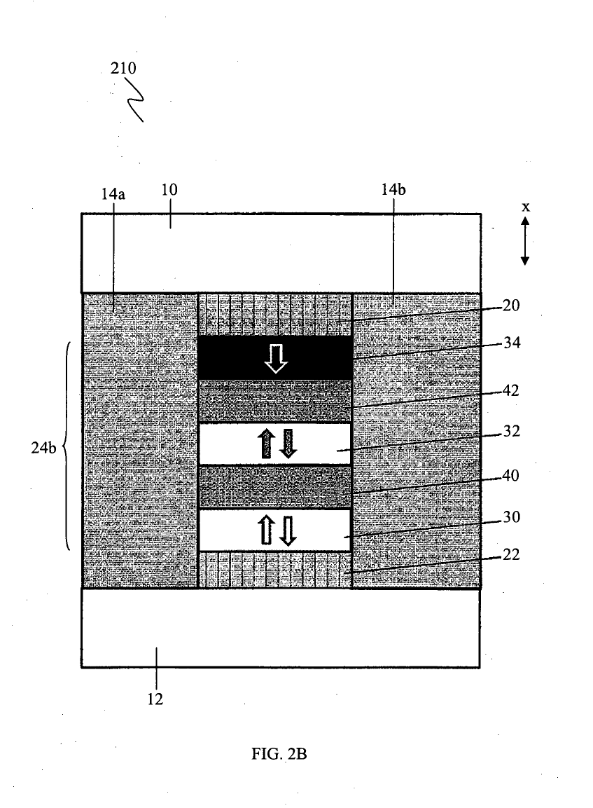

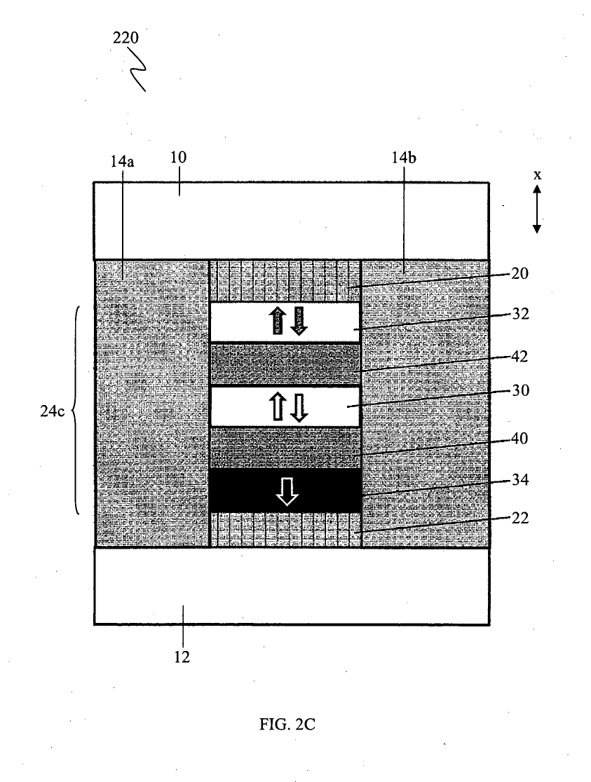

FIGS. 2A to 2C show schematic cross-sectional diagrams of a magnetoresistive device 200, 210, 220, having a magnetic junction 24a, 24b, 24c, respectively, according to various embodiments. The respective magnetic junction 24a, 24b, 24c, includes a giant magnetoresistive (GMR) dual pseudo-spin valve (D-PSV) with a current flowing perpendicular to the plane (CPP) direction. A current flowing in the respective magnetoresistive device 200, 210, 220, may flow in a perpendicular direction (e.g. as represented by a double-headed arrow in the x-direction) to the plane of the layers of the respective magnetic junction 24a, 24b, 24c.

The GMR D-PSV of the respective magnetic junction 24a, 24b, 24c, includes a fixed magnetic layer structure, for example a hard layer 34, as a reference layer and two free magnetic layer structures, for example a first soft layer 30 and a second soft layer 32, as storage layers. Each of the hard layer 34, the first soft layer 30 and the second soft layer 32 has its magnetic easy axis in a perpendicular direction (i.e. perpendicular anisotropy), for example as represented by the double-headed arrow in the x-direction. The hard layer 34 has a larger coercivity than each of the first soft layer 30 and the second soft layer 32.

As shown in FIGS. 2A to 2C, the arrow shown in the hard layer 34 illustrates the direction of magnetization orientation of the hard layer 34. While the arrow is shown pointing in a downward direction, it should be appreciated that the arrow may be illustrated as pointing in an upward direction, such that a magnetization orientation in the opposite direction to that of the embodiments of FIGS. 2A to 2C may be provided for the hard layer 34. In addition, the arrows shown in the first soft layer 30 and the second soft layer 32 illustrate the two directions of magnetization orientation of the first soft layer 30 and the second soft layer 32, such that the magnetization orientation may be in either of these two directions.

As shown in FIGS. 2A to 2C, each of the hard layer 34, the first soft layer 30 and the second soft layer 32, is separated from each other by a separation layer, for example a spacer layer.

For the embodiment of FIG. 2A with the magnetic junction 24a, the hard layer 34 is disposed between the first soft layer 30 and the second soft layer 32. In addition, a first spacer layer 40 is disposed between the hard layer 34 and the first soft layer 30, while a second spacer layer 42 is disposed between the hard layer 34 and the second soft layer 32.

For the embodiment of FIG. 2B with the magnetic junction 24b, the hard layer 34 is disposed over the first soft layer 30 and the second soft layer 32, such that the second soft layer 32 is in between the hard layer 34 and the first soft layer 30. In addition, a first spacer layer 40 is disposed between the first soft layer 30 and the second soft layer 32, while a second spacer layer 42 is disposed between the hard layer 34 and the second soft layer 32.

For the embodiment of FIG. 2C with the magnetic junction 24c, the hard layer 34 is disposed below the first soft layer 30 and the second soft layer 32, such that the first soft layer 30 is in between the hard layer 34 and the second soft layer 32. In addition, a first spacer layer 40 is disposed between the hard layer 34 and the first soft layer 30, while a second spacer layer 42 is disposed between the first soft layer 30 and the second soft layer 32.

In the embodiments of FIGS. 2A to 2C, each of the first spacer layer 40 and the second spacer layer 42 may be conductive and non-magnetic. For example, each of the first spacer layer 40 and the second spacer layer 42 may be a copper (Cu) spacer layer.

As shown in FIGS. 2A to 2C, each of the magnetoresistive devices 200, 210, 220, includes a capping layer structure 20, where the capping layer structure 20 is disposed over each of the magnetic junctions 24a, 24b, 24c. Each of the magnetoresistive devices 200, 210, 220, further includes a seed layer structure 22 where each of the magnetic junctions 24a, 24b, 24c, is disposed over the seed layer structure 22. Each of the magnetoresistive devices 200, 210, 220, further includes a first insulator 14a and a second insulator 14b. While not clearly illustrated in the schematic cross-sectional diagrams of FIGS. 2A to 2C, it should be appreciated that the first insulator 14a and the second insulator 14b may be a single insulator layer or a continuous insulator layer configured to surround the respective magnetic junction 24a, 24b, 24c. Each of the magnetoresistive devices 200, 210, 220, further includes a top electrode 10 and a bottom electrode 12 which may allow an electrical current to flow perpendicularly through the layers of the respective magnetic junction 24a, 24b, 24c.

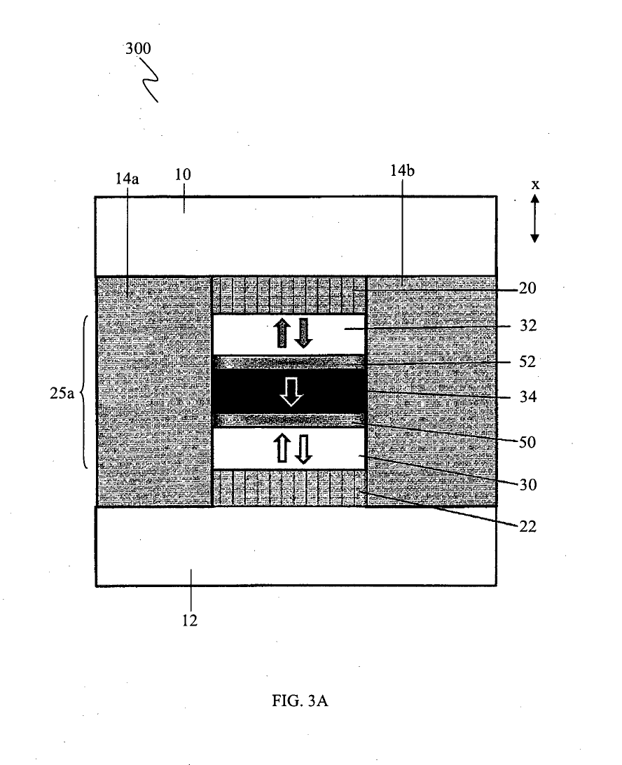

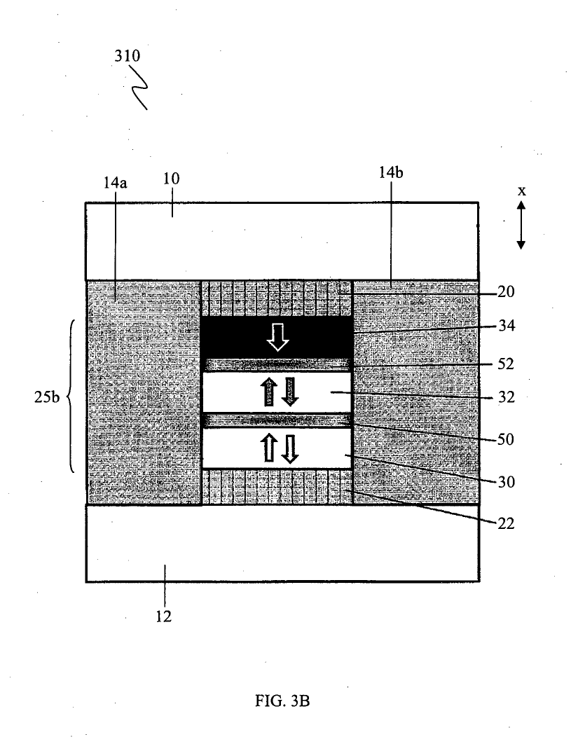

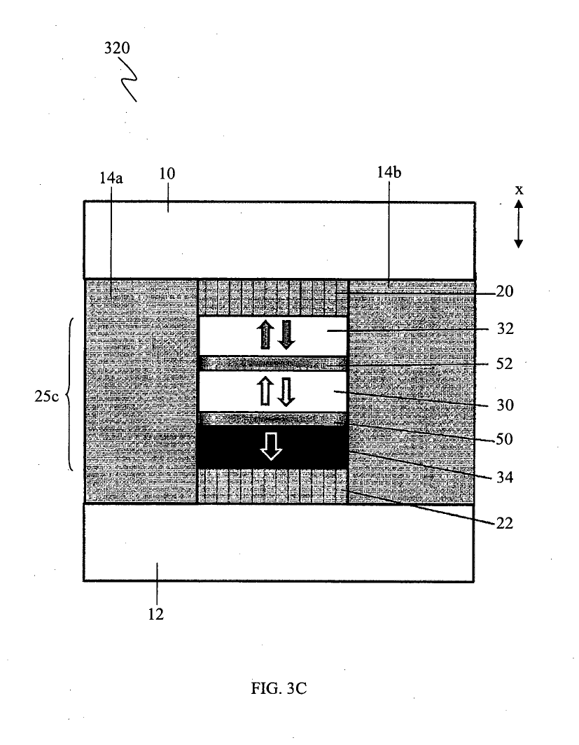

FIGS. 3A to 3C show schematic cross-sectional diagrams of a magnetoresistive device 300, 310, 320, having a magnetic junction 25a, 25b, 25c, respectively, according to various embodiments. The respective magnetic junction 25a, 25b, 25c, includes a tunnel magnetoresistive (TMR) dual pseudo-spin valve (D-PSV) with a current flowing perpendicular to the plane (CPP) direction. A current flowing in the respective magnetoresistive device 300, 310, 320, may flow in a perpendicular direction (e.g. as represented by a double-headed arrow in the x-direction) to the plane of the layers of the respective magnetic junction 25a, 25b, 25c.

The TMR D-PSV of the respective magnetic junction 25a, 25b, 25c, includes a fixed magnetic layer structure, for example a hard layer 34, as a reference layer and two free magnetic layer structures, for example a first soft layer 30 and a second soft layer 32, as storage layers. Each of the hard layer 34, the first soft layer 30 and the second soft layer 32 has its magnetic easy axis in a perpendicular direction (i.e. perpendicular anisotropy), for example as represented by the double-headed arrow in the x-direction. The hard layer 34 has a larger coercivity than each of the first soft layer 30 and the second soft layer 32.

As shown in FIGS. 3A to 3C, the arrow shown in the hard layer 34 illustrates the direction of magnetization orientation of the hard layer 34. While the arrow is shown pointing in a downward direction, it should be appreciated that the arrow may be illustrated as pointing in an upward direction, such that a magnetization orientation in the opposite direction to that of the embodiments of FIGS. 3A to 3C may be provided for the hard layer 34. In addition, the arrows shown in the first soft layer 30 and the second soft layer 32 illustrate the two directions of magnetization orientation of the first soft layer 30 and the second soft layer 32, such that the magnetization orientation may be in either of these two directions.

As shown in FIGS. 3A to 3C, each of the hard layer 34, the first soft layer 30 and the second soft layer 32, is separated from each other by a separation layer, for example a spacer layer in the form of a tunnel barrier.

For the embodiment of FIG. 3A with the magnetic junction 25a, the hard layer 34 is disposed between the first soft layer 30 and the second soft layer 32. In addition, a first tunnel barrier 50 is disposed between the hard layer 34 and the first soft layer 30, while a second tunnel barrier 52 is disposed between the hard layer 34 and the second soft layer 32.

For the embodiment of FIG. 3B with the magnetic junction 25b, the hard layer 34 is disposed over the first soft layer 30 and the second soft layer 32, such that the second soft layer 32 is in between the hard layer 34 and the first soft layer 30. In addition, a first tunnel barrier 50 is disposed between the first soft layer 30 and the second soft layer 32, while a second tunnel barrier 52 is disposed between the hard layer 34 and the second soft layer 32.

For the embodiment of FIG. 3C with the magnetic junction 25c, the hard layer 34 is disposed below the first soft layer 30 and the second soft layer 32, such that the first soft layer 30 is in between the hard layer 34 and the second soft layer 32. In addition, a first tunnel barrier 50 is disposed between the hard layer 34 and the first soft layer 30, while a second tunnel barrier 52 is disposed between the first soft layer 30 and the second soft layer 32.

In the embodiments of FIGS. 3A to 3C, each of the first tunnel barrier 50 and the second tunnel barrier 52 may be non-conductive and non-magnetic. For example, each of the first tunnel barrier 50 and the second tunnel barrier 52 may be an electrically insulating layer, including one of magnesium oxide (MgO), alumina (AlOₓ) and titanium oxide (TiOₓ).

As shown in FIGS. 3A to 3C, each of the magnetoresistive devices 300, 310, 320, includes a capping layer structure 20, where the capping layer structure 20 is disposed over each of the magnetic junctions 25a, 25b, 25c. Each of the magnetoresistive devices 300, 310, 320, further includes a seed layer structure 22 where each of the magnetic junctions 25a, 25b, 25c, is disposed over the seed layer structure 22. Each of the magnetoresistive devices 300, 310, 320, further includes a first insulator 14a and a second insulator 14b. While not clearly illustrated in the schematic cross-sectional diagrams of FIGS. 3A to 3C, it should be appreciated that the first insulator 14a and the second insulator 14b may be a single insulator layer or a continuous insulator layer configured to surround the respective magnetic junction 25a, 25b, 25c. Each of the magnetoresistive devices 300, 310, 320, further includes a top electrode 10 and a bottom electrode 12 which may allow an electrical current to flow perpendicularly through the layers of the respective magnetic junction 25a, 25b, 25c.

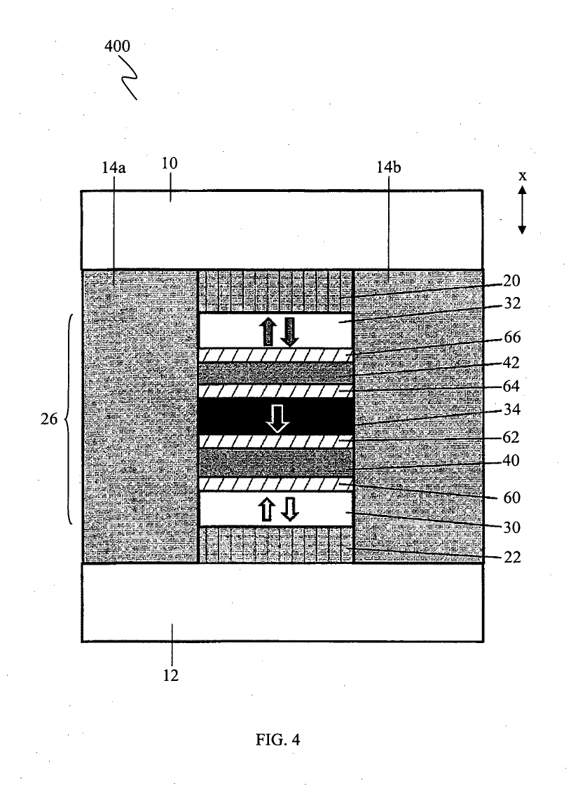

FIG. 4 shows a schematic cross-sectional diagram of a magnetoresistive device 400 having a magnetic junction 26 including spin filtering layers, according to various embodiments.

The magnetic junction 26 includes a giant magnetoresistive (GMR) dual pseudo-spin valve (D-PSV) with a current flowing perpendicular to the plane (CPP) direction. A current flowing in the magnetoresistive device 400, may flow in a perpendicular direction (e.g. as represented by a double-headed arrow in the x-direction) to the plane of the layers of the magnetic junction 26.

The GMR D-PSV of the magnetic junction 26 includes a fixed magnetic layer structure, for example a hard layer 34, as a reference layer and two free magnetic layer structures, for example a first soft layer 30 and a second soft layer 32, as storage layers. Each of the hard layer 34, the first soft layer 30 and the second soft layer 32 has its magnetic easy axis in a perpendicular direction (i.e. perpendicular anisotropy), for example as represented by the double-headed arrow in the x-direction. The hard layer 34 has a larger coercivity than each of the first soft layer 30 and the second soft layer 32.

As shown in FIG. 4, the arrow shown in the hard layer 34 illustrates the direction of magnetization orientation of the hard layer 34. While the arrow is shown pointing in a downward direction, it should be appreciated that the arrow may be illustrated as pointing in an upward direction, such that a magnetization orientation in the opposite direction to that of the embodiments of FIG. 4 may be provided for the hard layer 34. In addition, the arrows shown in the first soft layer 30 and the second soft layer 32 illustrate the two directions of magnetization orientation of the first soft layer 30 and the second soft layer 32, such that the magnetization orientation may be in either of these two directions.

As shown in FIG. 4, each of the hard layer 34, the first soft layer 30 and the second soft layer 32, is separated from each other by a separation layer, for example a spacer layer. For the embodiment of FIG. 4 with the magnetic junction 26, the hard layer 34 is disposed between the first soft layer 30 and the second soft layer 32. In addition, a first spacer layer 40 is disposed between the hard layer 34 and the first soft layer 30, while a second spacer layer 42 is disposed between the hard layer 34 and the second soft layer 32. Each of the first spacer layer 40 and the second spacer layer 42 may be conductive and non-magnetic. For example, each of the first spacer layer 40 and the second spacer layer 42 may be a copper (Cu) spacer layer.

The magnetic junction 26 further includes a plurality of spin filtering (SF) layers between the hard layer 34, the first soft layer 30, the second soft layer 32, the first spacer layer 40 and the second spacer layer 42, configured to tune the spin polarization ratio at the interfaces of these layers and/or to control the resistance level of the magnetic junction 26.

As shown in FIG. 4, a first spin filtering layer 60 is disposed between the first soft layer 30 and the first spacer layer 40, a second spin filtering layer 62 is disposed between the first spacer layer 40 and the hard layer 34, a third spin filtering layer 64 is disposed between the hard layer 34 and the second spacer layer 42, and a fourth spin filtering layer 66 is disposed between the second spacer layer 42 and the second soft layer 32.

As shown in FIG. 4, the magnetoresistive device 400 includes a capping layer structure 20, where the capping layer structure 20 is disposed over the magnetic junction 26. The magnetoresistive device 400 further includes a seed layer structure 22 where the magnetic junction 26 is disposed over the seed layer structure 22. The magnetoresistive device 400 further includes a first insulator 14a and a second insulator 14b. While not clearly illustrated in the schematic cross-sectional diagram of FIG. 4, it should be appreciated that the first insulator 14a and the second insulator 14b may be a single insulator layer or a continuous insulator layer configured to surround the magnetic junction 26. The magnetoresistive device 400 further includes a top electrode 10 and a bottom electrode 12 which may allow an electrical current to flow perpendicularly through the layers of the magnetic junction 26.

In various embodiments, each of the first spin filtering layer 60, the second spin filtering layer 62, the third spin filtering layer 64 and the fourth spin filtering layer 66 may include a single layer or multiple layers, for example two layers, three layers, four layers or any higher number of layers, depending on user, design and application requirements.

In various embodiments, at least one spin filtering layer is provided between one of the hard layer 34, the first soft layer 30 and the second soft layer 32, and one of the non-magnetic first spacer layer 40 and the non-magnetic second spacer layer 42. Accordingly, it should be appreciated that any number of filtering layer may be provided in between one of the hard layer 34, the first soft layer 30 and the second soft layer 32, and one of the non-magnetic first spacer layer 40 and the non-magnetic second spacer layer 42, such as two, three, four or any higher number of spin filtering layers.

While FIG. 4 shows four spin filtering layers (i.e. the first spin filtering layer 60, the second spin filtering layer 62, the third spin filtering layer 64 and the fourth spin filtering layer 66), it should be appreciated that any number of spin filtering layers may be provided, for example one, two, three, four, five, six or any higher number of spin filtering layers, depending on user, design and application requirements. As an example and not limitation, the second spin filtering layer 62 of FIG. 4 may be removed such that the hard layer 34 may be in contact with the first spacer layer 40, or a fifth spin filtering layer may be provided, for example between the first soft layer 30 and the seed layer structure 22.

Furthermore, while FIG. 4 shows that spin filtering layers are provided for the magnetic junction 26 where the hard layer 34 is disposed between the first soft layer 30 and the second soft layer 32, similar to the configuration of the GMR D-PSV of the magnetic junction 24a of FIG. 2A, it should be appreciated that spin filtering layers may be similarly provided to a magnetic junction with a similar configuration to the GMR D-PSV of the magnetic junction 24b of FIG. 2B and the magnetic junction 24c of FIG. 2C, and also to the TMR D-PSV of the magnetic junction 25a of FIG. 3A, the magnetic junction 25b of FIG. 3B and the magnetic junction 25c of FIG. 3C, such that descriptions relating to the embodiment of FIG. 4 relating to spin filtering layers may correspondingly be applicable.

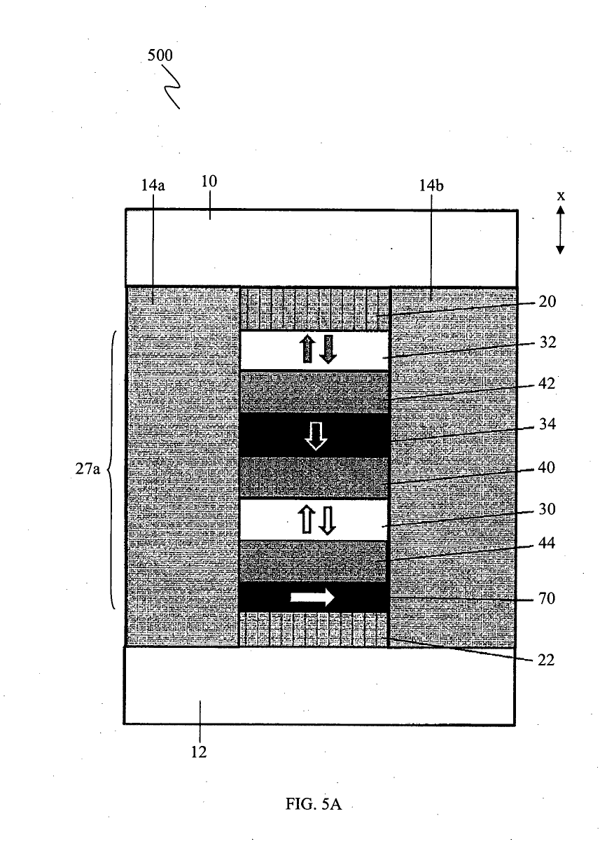

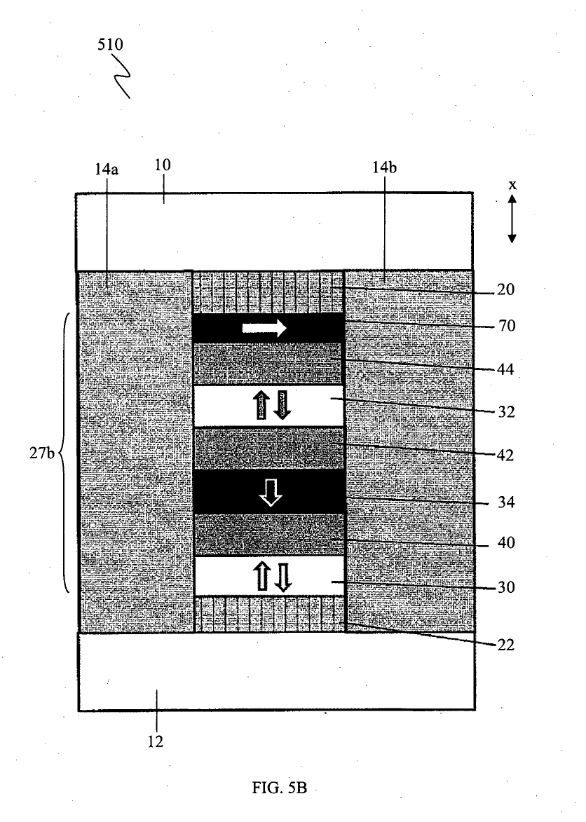

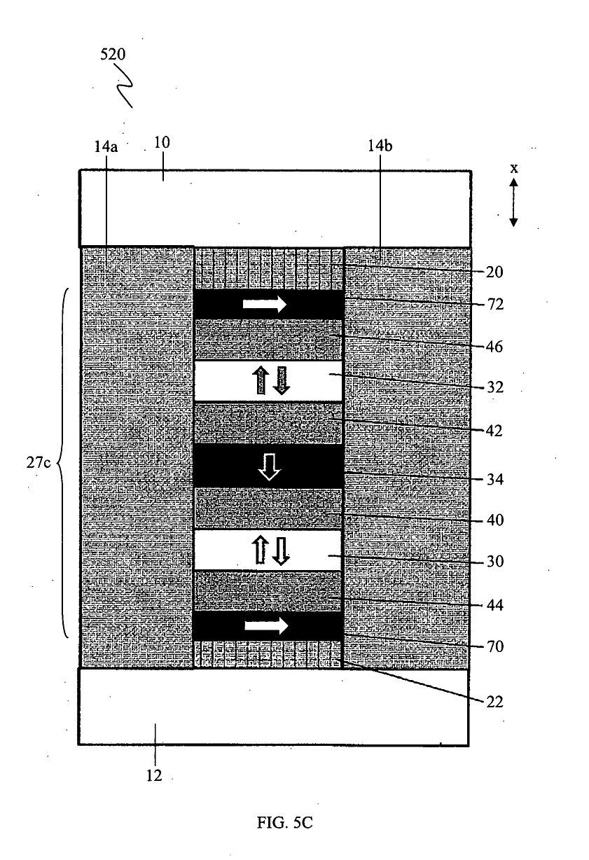

FIGS. 5A to 5C show schematic cross-sectional diagrams of a magnetoresistive device 500, 510, 520, having a magnetic junction 27a, 27b, 27c, respectively, including in-plane spin polarizer layers, according to various embodiments.

The respective magnetic junction 27a, 27b, 27c, includes a giant magnetoresistive (GMR) dual pseudo-spin valve (D-PSV) with a current flowing perpendicular to the plane (CPP) direction. A current flowing in the respective magnetoresistive device 500, 510, 520, may flow in a perpendicular direction (e.g. as represented by a double-headed arrow in the x-direction) to the plane of the layers of the respective magnetic junction 27a, 27b, 27c.

The GMR D-PSV of the respective magnetic junction 27a, 27b, 27c, includes a fixed magnetic layer structure, for example a hard layer 34, as a reference layer and two free magnetic layer structures, for example a first soft layer 30 and a second soft layer 32, as storage layers. Each of the hard layer 34, the first soft layer 30 and the second soft layer 32 has its magnetic easy axis in a perpendicular direction (i.e. perpendicular anisotropy), for example as represented by the double-headed arrow in the x-direction. The hard layer 34 has a larger coercivity than each of the first soft layer 30 and the second soft layer 32.

As shown in FIGS. 5A to 5C, the arrow shown in the hard layer 34 illustrates the direction of magnetization orientation of the hard layer 34. While the arrow is shown pointing in a downward direction, it should be appreciated that the arrow may be illustrated as pointing in an upward direction, such that a magnetization orientation in the opposite direction to that of the embodiments of FIGS. 5A to 5C may be provided for the hard layer 34. In addition, the arrows shown in the first soft layer 30 and the second soft layer 32 illustrate the two directions of magnetization orientation of the first soft layer 30 and the second soft layer 32, such that the magnetization orientation may be in either of these two directions.

As shown in FIGS. 5A to 5C, each of the hard layer 34, the first soft layer 30 and the second soft layer 32, is separated from each other by a separation layer, for example a spacer layer. For the embodiments of FIGS. 5A to 5C, the hard layer 34 is disposed between the first soft layer 30 and the second soft layer 32. In addition, a first spacer layer 40 is disposed between the hard layer 34 and the first soft layer 30, while a second spacer layer 42 is disposed between the hard layer 34 and the second soft layer 32.

For the embodiment of FIG. 5A with the magnetic junction 27a, the magnetic junction 27a further includes an in-plane spin polarizer layer 70 adjacent to the first soft layer 30, with a third spacer layer 44 disposed in between the first soft layer 30 and the in-plane spin polarizer layer 70. The in-plane spin polarizer layer 70 is provided in order to reduce the writing current of the first soft layer 30.

For the embodiment of FIG. 5B with the magnetic junction 27b, the magnetic junction 27b further includes an in-plane spin polarizer layer 70 adjacent to the second soft layer 32, with a third spacer layer 44 disposed in between the second soft layer 32 and the in-plane spin polarizer layer 70. The in-plane spin polarizer layer 70 is provided in order to reduce the writing current of the second soft layer 32.

For the embodiment of FIG. 5C with the magnetic junction 27c, the magnetic junction 27c further includes a first in-plane spin polarizer layer 70 adjacent to the first soft layer 30, with a third spacer layer 44 disposed in between the first soft layer 30 and the first in-plane spin polarizer layer 70. The first in-plane spin polarizer layer 70 is provided in order to reduce the writing current of the first soft layer 30.

The magnetic junction 27c further includes a second in-plane spin polarizer layer 72 adjacent to the second soft layer 32, with a fourth spacer layer 46 disposed in between the second soft layer 32 and the second in-plane spin polarizer layer 72. The second in-plane spin polarizer layer 72 is provided in order to reduce the writing current of the second soft layer 32.

In various embodiments, providing a respective in-plane spin polarizer layer to either one or both of the soft layers may be effective for adjusting or modifying the switching current of the soft layers for switching the magnetization orientation of the soft layers between the parallel direction and the anti-parallel direction. In embodiments where the magnetoresistive device is a magnetic memory element, the respective in-plane spin polarizer layer may be configured to facilitate adjustment of the switching current to provide clear separation of states for data storage.

As shown in FIGS. 5A to 5C, the arrow shown in the in-plane spin polarizer layer 70 (FIGS. 5A and 5B) or the first in-plane spin polarizer layer 70 (FIG. 5C), and the second in-plane spin polarizer layer 72 (FIG. 5C) illustrates the direction of magnetization orientation of the different in-plane spin polarizer layers, which is in a direction perpendicular to the direction of magnetization orientation of the hard layer 34, the first soft layer 30 and the second soft layer 32. In other words, the in-plane spin polarizer layer 70 (FIGS. 5A and 5B) or the first in-plane spin polarizer layer 70 (FIG. 5C), and the second in-plane spin polarizer layer 72 (FIG. 5C) include a magnetization orientation in a direction substantially parallel to a plane defined by an interface between the hard layer 34 and either one of the first soft layer 30 and the second soft layer 32. In addition, while the arrow is shown pointing in a direction to the right, it should be appreciated that the arrow may be illustrated as pointing in a direction to the left, such that a magnetization orientation in the opposite direction to that of the embodiments of FIGS. 5A to 5C may be provided for the different in-plane spin polarizer layers.

In various embodiments, other methods for varying or modifying the switching current of the soft layers may be employed, including but not limited to providing composite soft layers having more than one material, in addition to or alternatively to providing in-plane spin polarizer layers. In these embodiments, the in-plane spin polarizer layers may be optional and therefore, the magnetic junction may include, for example, a hard layer and two composite soft layers.

In the embodiments of FIGS. 5A to 5C, each of the first spacer layer 40, the second spacer layer 42, the third spacer layer 44 and the fourth spacer layer 46 may be conductive and non-magnetic. For example, each of the first spacer layer 40, the second spacer layer 42, the third spacer layer 44 and the fourth spacer layer 46 may be a copper (Cu) spacer layer.

As shown in FIGS. 5A to 5C, each of the magnetoresistive devices 500, 510, 520, includes a capping layer structure 20, where the capping layer structure 20 is disposed over each of the magnetic junctions 27a, 27b, 27c. Each of the magnetoresistive devices 500, 510, 520, further includes a seed layer structure 22 where each of the magnetic junctions 27a, 27b, 27c, is disposed over the seed layer structure 22. Each of the magnetoresistive devices 500, 510, 520, further includes a first insulator 14a and a second insulator 14b. While not clearly illustrated in the schematic cross-sectional diagrams of FIGS. 5A to 5C, it should be appreciated that the first insulator 14a and the second insulator 14b may be a single insulator layer or a continuous insulator layer configured to surround the respective magnetic junction 27a, 27b, 27c. Each of the magnetoresistive devices 500, 510, 520, further includes a top electrode 10 and a bottom electrode 12 which may allow an electrical current to flow perpendicularly through the layers of the respective magnetic junction 27a, 27b, 27c.

It addition, it should be appreciated that one or more spin filtering layers may be provided for the magnetic junction 27a of FIG. 5A, the magnetic junction 27b of FIG. 5B and the magnetic junction 27c of FIG. 5C, such that descriptions relating to spin filtering layers of the embodiment of FIG. 4 may correspondingly be applicable.

In various embodiments, each of the in-plane spin polarizer layer 70 or the first in-plane spin polarizer layer 70, and the second in-plane spin polarizer layer 72 may include a single layer or multiple layers, for example two layers, three layers, four layers or any higher number of layers.

In various embodiments, at least one in-plane spin polarizer layer is provided adjacent to either or both of the first soft layer 30 and the second soft layer 32. Accordingly, it should be appreciated that any number of in-plane spin polarizer layer may be provided adjacent to either or both of the first soft layer 30 and the second soft layer 32, such as two, three, four or any higher number of in-plane spin polarizer layers.

While FIGS. 5A to 5C shows that one or more in-plane spin polarizer layers are provided for the respective magnetic junction 27a, 27b, 27c, where the hard layer 34 is disposed between the first soft layer 30 and the second soft layer 32, similar to the configuration of the GMR D-PSV of the magnetic junction 24a of FIG. 2A, it should be appreciated that the one or more in-plane spin polarizer layers may be similarly provided to a magnetic junction with a similar configuration to the GMR D-PSV of the magnetic junction 24b of FIG. 2B and the magnetic junction 24c of FIG. 2C, and also to the TMR D-PSV of the magnetic junction 25a of FIG. 3A, the magnetic junction 25b of FIG. 3B and the magnetic junction 25c of FIG. 3C, such that descriptions relating to the embodiments of FIGS. 5A to 5C relating to in-plane spin polarizer layers may correspondingly be applicable.

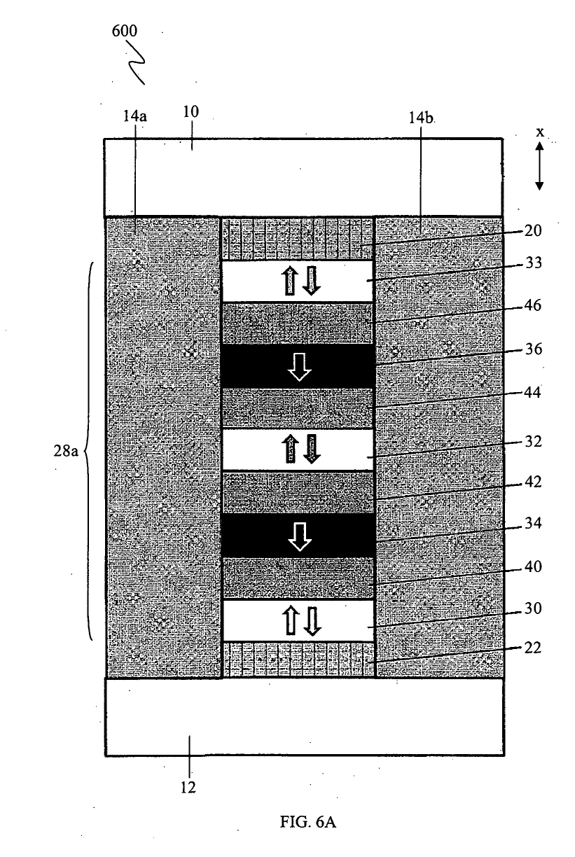

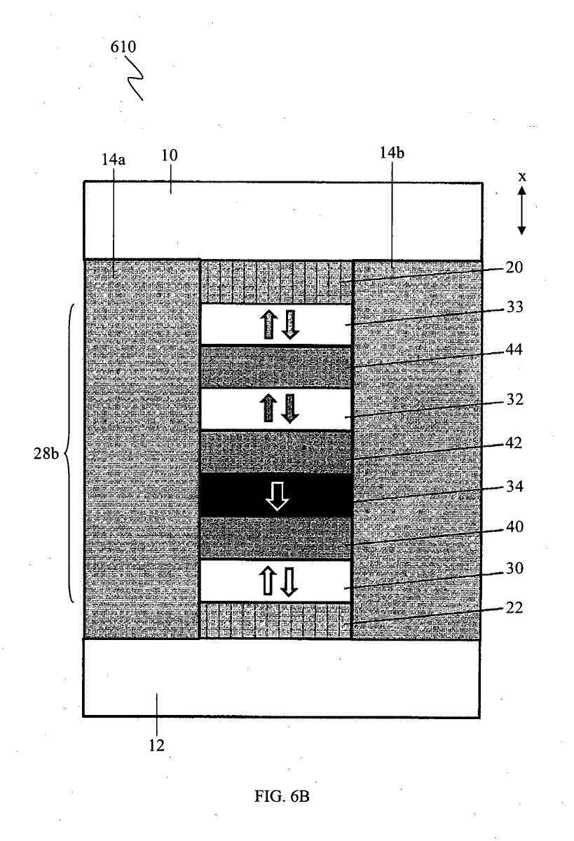

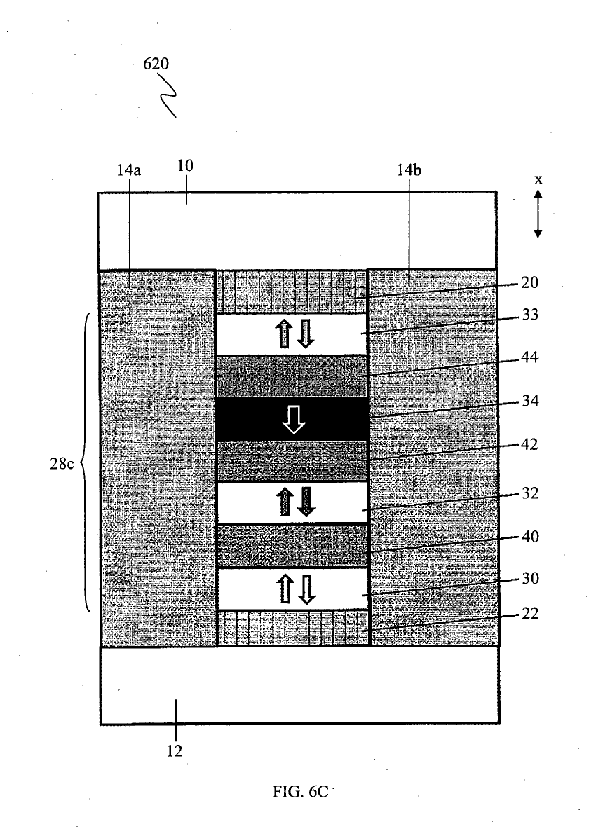

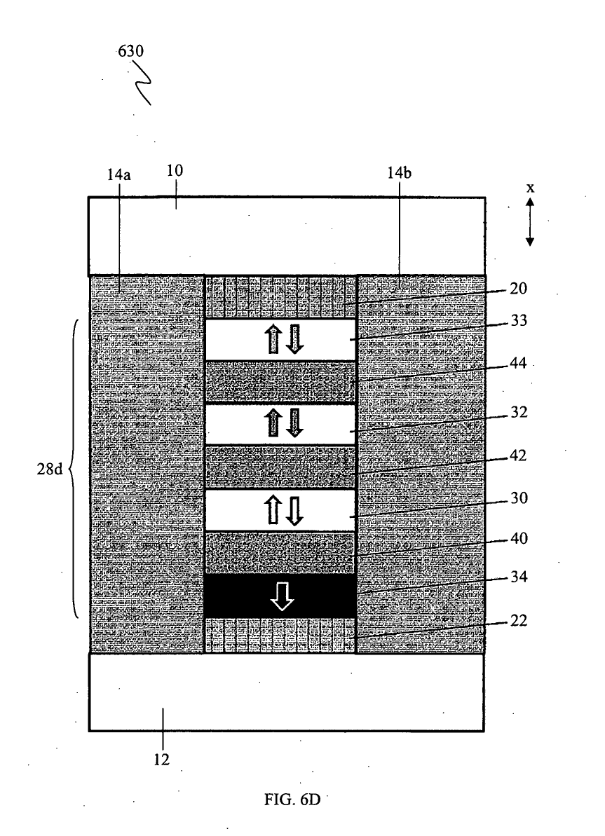

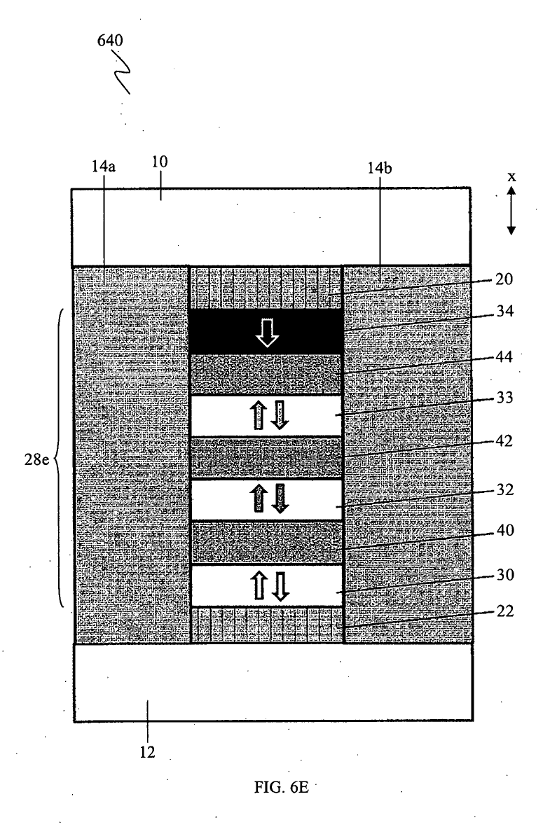

FIGS. 6A to 6E show schematic cross-sectional diagrams of a magnetoresistive device 600, 610, 620, 630, 640, having a magnetic junction 28a, 28b, 28c, 28d, 28e, respectively, according to various embodiments. The respective magnetic junction 28a, 28b, 28c, 28d, 28e, includes a giant magnetoresistive (GMR) triple pseudo-spin valve (T-PSV) with a current flowing perpendicular to the plane (CPP) direction. A current flowing in the respective magnetoresistive device 600, 610, 620, 630, 640, may flow in a perpendicular direction (e.g. as represented by a double-headed arrow in the x-direction) to the plane of the layers of the respective magnetic junction 28a, 28b, 28c, 28d, 28e.

The GMR T-PSV of the respective magnetic junction 28a, 28b, 28c, 28d, 28e, includes at least one fixed magnetic layer structure as a reference layer, for example a hard layer 34, or a first hard layer 34 and a second hard layer 36, and three free magnetic layer structures, for example a first soft layer 30, a second soft layer 32 and a third soft layer 33, as storage layers. Each of the hard layer 34 or the first hard layer 34, the second hard layer 36, the first soft layer 30, the second soft layer 32 and the third soft layer 33 has its magnetic easy axis in a perpendicular direction (i.e. perpendicular anisotropy), for example as represented by the double-headed arrow in the x-direction. Each of the hard layer 34 or the first hard layer 34, and the second hard layer 36 has a larger coercivity than each of the first soft layer 30, the second soft layer 32 and the third soft layer 33.

As shown in FIGS. 6A to 6E, the arrow shown in the hard layer 34 or the first hard layer 34, and the second hard layer 36, illustrates the direction of magnetization orientation of the hard layer 34 or the first hard layer 34, and the second hard layer 36. While the arrow is shown pointing in a downward direction, it should be appreciated that the arrow may be illustrated as pointing in an upward direction, such that a magnetization orientation in the opposite direction to that of the embodiments of FIGS. 6A to 6E may be provided for the hard layer 34 or the first hard layer 34, and the second hard layer 36. In addition, the arrows shown in the first soft layer 30, the second soft layer 32 and the third soft layer 33, illustrate the two directions of magnetization orientation of the first soft layer 30, the second soft layer 32 and the third soft layer 33, such that the magnetization orientation may be in either of these two directions.

As shown in FIGS. 6A to 6E, adjacent magnetic layer structures (e.g. a hard layer and a soft layer, or two soft layers) are separated from each other by a separation layer, for example a spacer layer.

For the embodiment of FIG. 6A with the magnetic junction 28a, the first hard layer 34 is disposed between the first soft layer 30 and the second soft layer 32, while the second hard layer 36 is disposed between the second soft layer 32 and the third soft layer 33. In addition, a first spacer layer 40 is disposed between the first hard layer 34 and the first soft layer 30, a second spacer layer 42 is disposed between the hard layer 34 and the second soft layer 32, a third spacer layer 44 is disposed between the second soft layer 32 and the second hard layer 36, while a fourth spacer layer 46 is disposed between the second hard layer 36 and the third soft layer 33.

For the embodiment of FIG. 6B with the magnetic junction 28b, the hard layer 34 is disposed between the first soft layer 30 and the second soft layer 32, and below the second soft layer 32 and the third soft layer 33. In addition, a first spacer layer 40 is disposed between the hard layer 34 and the first soft layer 30, a second spacer layer 42 is disposed between the hard layer 34 and the second soft layer 32, while a third spacer layer 44 is disposed between the second soft layer 32 and the third soft layer 33.

For the embodiment of FIG. 6C with the magnetic junction 28c, the hard layer 34 is disposed between the second soft layer 32 and the third soft layer 33, and over the first soft layer 30 and the second soft layer 32. In addition, a first spacer layer 40 is disposed between the first soft layer 30 and the second soft layer 32, a second spacer layer 42 is disposed between the hard layer 34 and the second soft layer 32, while a third spacer layer 44 is disposed between the hard layer 34 and the third soft layer 33.

For the embodiment of FIG. 6D with the magnetic junction 28d, the hard layer 34 is disposed below the first soft layer 30, the second soft layer 32 and the third soft layer 33. In addition, a first spacer layer 40 is disposed between the hard layer 34 and the first soft layer 30, a second spacer layer 42 is disposed between the first soft layer 30 and the second soft layer 32, while a third spacer layer 44 is disposed between the second soft layer 32 and the third soft layer 33.

For the embodiment of FIG. 6E with the magnetic junction 28e, the hard layer 34 is disposed over the first soft layer 30, the second soft layer 32 and the third soft layer 33. In addition, a first spacer layer 40 is disposed between the first soft layer 30 and the second soft layer 32, a second spacer layer 42 is disposed between the second soft layer 32 and the third soft layer 33, while a third spacer layer 44 is disposed between the hard layer 34 and the third soft layer 33.

In the embodiments of FIGS. 6A to 6E, each of the first spacer layer 40, the second spacer layer 42, the third spacer layer 44 and the fourth spacer layer 46 may be conductive and non-magnetic. For example, each of the first spacer layer 40, the second spacer layer 42, the third spacer layer 44 and the fourth spacer layer 46 may be a copper (Cu) spacer layer.

As shown in FIGS. 6A to 6E, each of the magnetoresistive devices 600, 610, 620, 630, 640, includes a capping layer structure 20, where the capping layer structure 20 is disposed over each of the magnetic junctions 28a, 28b, 28c, 28d, 28e. Each of the magnetoresistive devices 600, 610, 620, 630, 640, further includes a seed layer structure 22 where each of the magnetic junctions 28a, 28b, 28c, 28d, 28e, is disposed over the seed layer structure 22. Each of the magnetoresistive devices 600, 610, 620, 630, 640, further includes a first insulator 14a and a second insulator 14b. While not clearly illustrated in the schematic cross-sectional diagrams of FIGS. 6A to 6E, it should be appreciated that the first insulator 14a and the second insulator 14b may be a single insulator layer or a continuous insulator layer configured to surround the respective magnetic junction 28a, 28b, 28c, 28d, 28e. Each of the magnetoresistive devices 600, 610, 620, 630, 640, further includes a top electrode 10 and a bottom electrode 12 which may allow an electrical current to flow perpendicularly through the layers of the respective magnetic junction 28a, 28b, 28c, 28d, 28e.

It should be appreciated that for the embodiment of FIG. 6A, the first hard layer 34 may be disposed between the seed layer structure 22 and the first soft layer 30, with a spacer layer in between the first hard layer 34 and the first soft layer 30, and/or that the second hard layer 36 may be disposed between the capping layer structure 20 and the third soft layer 33, with a spacer layer in between the second hard layer 36 and the third soft layer 33.

In addition, it should be appreciated that for the embodiment of FIG. 6A, a third hard layer may be disposed between the seed layer structure 22 and the first soft layer 30, with a spacer layer in between the third hard layer and the first soft layer 30, or that a third hard layer may be disposed between the capping layer structure 20 and the third soft layer 33, with a spacer layer in between the third hard layer and the third soft layer 33.

In addition, it should be appreciated that for the embodiment of FIG. 6A, a third hard layer may be disposed between the seed layer structure 22 and the first soft layer 30, with a spacer layer in between the third hard layer and the first soft layer 30, and that a fourth hard layer may be disposed between the capping layer structure 20 and the third soft layer 33, with a spacer layer in between the fourth hard layer and the third soft layer 33.

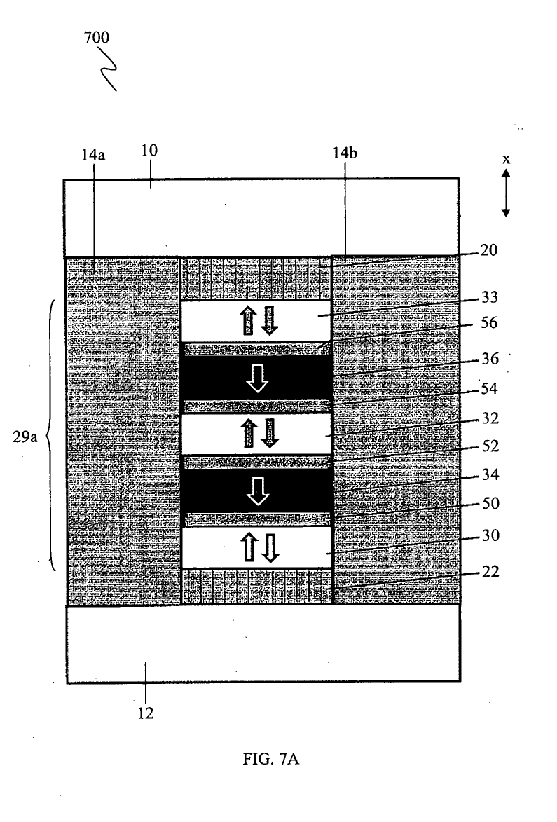

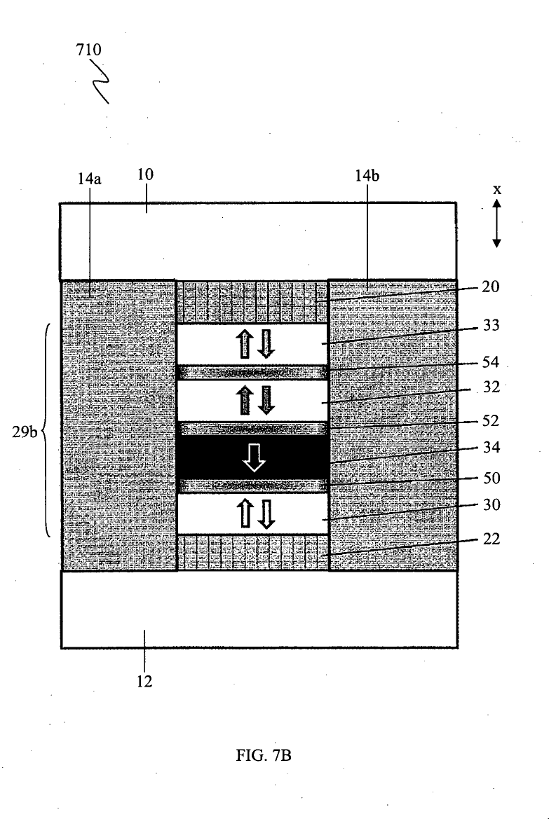

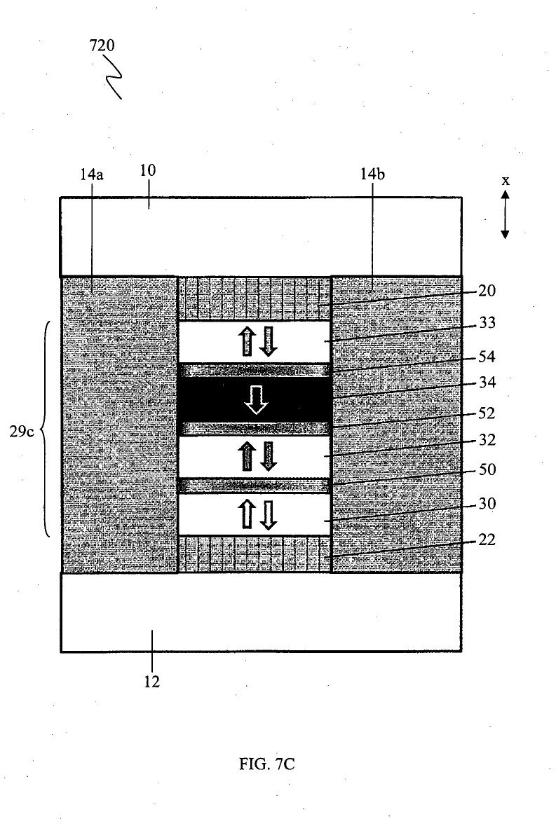

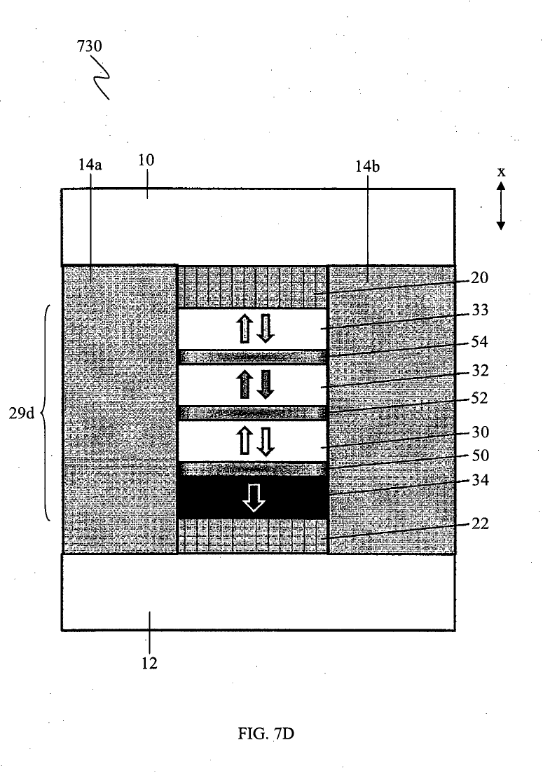

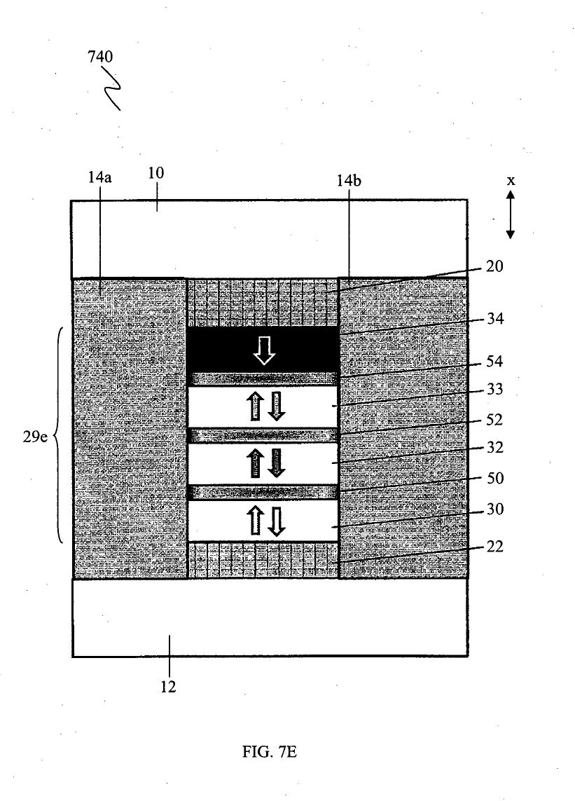

FIGS. 7A to 7E show schematic cross-sectional diagrams of a magnetoresistive device 700, 710, 720, 730, 740, having a magnetic junction 29a, 29b, 29c, 29d, 29e, respectively, according to various embodiments. The respective magnetic junction 29a, 29b, 29c, 29d, 29e, includes a tunnel magnetoresistive (TMR) triple pseudo-spin valve (T-PSV) with a current flowing perpendicular to the plane (CPP) direction. A current flowing in the respective magnetoresistive device 700, 710, 720, 730, 740, may flow in a perpendicular direction (e.g. as represented by a double-headed arrow in the x-direction) to the plane of the layers of the respective magnetic junction 29a, 29b, 29c, 29d, 29e.

The TMR T-PSV of the respective magnetic junction 29a, 29b, 29c, 29d, 29e, includes at least one fixed magnetic layer structure as a reference layer, for example a hard layer 34, or a first hard layer 34 and a second hard layer 36, and three free magnetic layer structures, for example a first soft layer 30, a second soft layer 32 and a third soft layer 33, as storage layers. Each of the hard layer 34 or the first hard layer 34, the second hard layer 36, the first soft layer 30, the second soft layer 32 and the third soft layer 33 has its magnetic easy axis in a perpendicular direction (i.e. perpendicular anisotropy), for example as represented by the double-headed arrow in the x-direction. Each of the hard layer 34 or the first hard layer 34, and the second hard layer 36 has a larger coercivity than each of the first soft layer 30, the second soft layer 32 and the third soft layer 33.

As shown in FIGS. 7A to 7E, the arrow shown in the hard layer 34 or the first hard layer 34, and the second hard layer 36, illustrates the direction of magnetization orientation of the hard layer 34 or the first hard layer 34, and the second hard layer 36. While the arrow is shown pointing in a downward direction, it should be appreciated that the arrow may be illustrated as pointing in an upward direction, such that a magnetization orientation in the opposite direction to that of the embodiments of FIGS. 7A to 7E may be provided for the hard layer 34 or the first hard layer 34, and the second hard layer 36. In addition, the arrows shown in the first soft layer 30, the second soft layer 32 and the third soft layer 33, illustrate the two directions of magnetization orientation of the first soft layer 30, the second soft layer 32 and the third soft layer 33, such that the magnetization orientation may be in either of these two directions.

As shown in FIGS. 7A to 7E, adjacent magnetic layer structures (e.g. a hard layer and a soft layer, or two soft layers) are separated from each other by a separation layer, for example a spacer layer in the form of a tunnel barrier.

For the embodiment of FIG. 7A with the magnetic junction 29a, the first hard layer 34 is disposed between the first soft layer 30 and the second soft layer 32, while the second hard layer 36 is disposed between the second soft layer 32 and the third soft layer 33. In addition, a first tunnel barrier 50 is disposed between the first hard layer 34 and the first soft layer 30, a second tunnel barrier 52 is disposed between the hard layer 34 and the second soft layer 32, a third tunnel barrier 54 is disposed between the second soft layer 32 and the second hard layer 36, while a fourth tunnel barrier 56 is disposed between the second hard layer 36 and the third soft layer 33.

For the embodiment of FIG. 7B with the magnetic junction 29b, the hard layer 34 is disposed between the first soft layer 30 and the second soft layer 32, and below the second soft layer 32 and the third soft layer 33. In addition, a first tunnel barrier 50 is disposed between the hard layer 34 and the first soft layer 30, a second tunnel barrier 52 is disposed between the hard layer 34 and the second soft layer 32, while a third tunnel barrier 54 is disposed between the second soft layer 32 and the third soft layer 33.

For the embodiment of FIG. 7C with the magnetic junction 29c, the hard layer 34 is disposed between the second soft layer 32 and the third soft layer 33, and over the first soft layer 30 and the second soft layer 32. In addition, a first tunnel barrier 50 is disposed between the first soft layer 30 and the second soft layer 32, a second tunnel barrier 52 is disposed between the hard layer 34 and the second soft layer 32, while a third tunnel barrier 54 is disposed between the hard layer 34 and the third soft layer 33.

For the embodiment of FIG. 7D with the magnetic junction 29d, the hard layer 34 is disposed below the first soft layer 30, the second soft layer 32 and the third soft layer 33. In addition, a first tunnel barrier 50 is disposed between the hard layer 34 and the first soft layer 30, a second tunnel barrier 52 is disposed between the first soft layer 30 and the second soft layer 32, while a third tunnel barrier 54 is disposed between the second soft layer 32 and the third soft layer 33.

For the embodiment of FIG. 7E with the magnetic junction 29e, the hard layer 34 is disposed over the first soft layer 30, the second soft layer 32 and the third soft layer 33. In addition, a first tunnel barrier 50 is disposed between the first soft layer 30 and the second soft layer 32, a second tunnel barrier 52 is disposed between the second soft layer 32 and the third soft layer 33, while a third tunnel barrier 54 is disposed between the hard layer 34 and the third soft layer 33.

In the embodiments of FIGS. 7A to 7E, each of the first tunnel barrier 50, the second tunnel barrier 52, the third tunnel barrier 54 and the fourth tunnel barrier 56 may be non-conductive and non-magnetic. For example, each of the first tunnel barrier 50, the second tunnel barrier 52, the third tunnel barrier 54 and the fourth tunnel barrier 56 may be an electrically insulating layer, including one of magnesium oxide (MgO), alumina (AlOₓ) and titanium oxide (TiOₓ).

As shown in FIGS. 7A to 7E, each of the magnetoresistive devices 700, 710, 720, 730, 740, includes a capping layer structure 20, where the capping layer structure 20 is disposed over each of the magnetic junctions 29a, 29b, 29c, 29d, 29e. Each of the magnetoresistive devices 700, 710, 720, 730, 740, further includes a seed layer structure 22 where each of the magnetic junctions 29a, 29b, 29c, 29d, 29e, is disposed over the seed layer structure 22. Each of the magnetoresistive devices 700, 710, 720, 730, 740, further includes a first insulator 14a and a second insulator 14b. While not clearly illustrated in the schematic cross-sectional diagrams of FIGS. 6A to 6E, it should be appreciated that the first insulator 14a and the second insulator 14b may be a single insulator layer or a continuous insulator layer configured to surround the respective magnetic junction 29a, 29b, 29c, 29d, 29e. Each of the magnetoresistive devices 700, 710, 720, 730, 740, further includes a top electrode 10 and a bottom electrode 12 which may allow an electrical current to flow perpendicularly through the layers of the respective magnetic junction 29a, 29b, 29c, 29d, 29e.

It should be appreciated that for the embodiment of FIG. 7A, the first hard layer 34 may alternatively be disposed between the seed layer structure 22 and the first soft layer 30, with a tunnel barrier in between the first hard layer 34 and the first soft layer 30, and/or that the second hard layer 36 may be disposed between the capping layer structure 20 and the third soft layer 33, with a tunnel barrier in between the second hard layer 36 and the third soft layer 33.

In addition, it should be appreciated that for the embodiment of FIG. 7A, a third hard layer may be disposed between the seed layer structure 22 and the first soft layer 30, with a tunnel barrier in between the third hard layer and the first soft layer 30, or that a third hard layer may be disposed between the capping layer structure 20 and the third soft layer 33, with a tunnel barrier in between the third hard layer and the third soft layer 33.

In addition, it should be appreciated that for the embodiment of FIG. 7A, a third hard layer may be disposed between the seed layer structure 22 and the first soft layer 30, with a tunnel barrier in between the third hard layer and the first soft layer 30, and that a fourth hard layer may be disposed between the capping layer structure 20 and the third soft layer 33, with a tunnel barrier in between the fourth hard layer and the third soft layer 33.

It should be appreciated that one or more spin filtering layers and/or one or more in-plane spin polarizer layers may be provided for the magnetic junction 28a of FIG. 6A, the magnetic junction 28b of FIG. 6B, the magnetic junction 28c of FIG. 6C, the magnetic junction 28d of FIG. 6D, the magnetic junction 28e of FIG. 6E, the magnetic junction 29a of FIG. 7A, the magnetic junction 29b of FIG. 7B, the magnetic junction 29c of FIG. 7C, the magnetic junction 29d of FIG. 7D and the magnetic junction 29e of FIG. 7E, such that descriptions relating to spin filtering layers of the embodiment of FIG. 4 and the in-plane spin polarizer layers of the embodiment of FIG. 5A to 5C may correspondingly be applicable.

In the context of various embodiments of FIGS. 2A to 2C, 3A to 3C, 4, 5A to 5C, 6A to 6E and 7A to 7E, each of the capping layer structure 20, the seed layer structure 22, the hard layer 34 or the first hard layer 34, the second hard layer 36, the first soft layer 30, the second soft layer 32, the third soft layer 33, the first spacer layer 40, the second spacer layer 42, the third spacer layer 44, the fourth spacer layer 46, the first tunnel barrier 50, the second tunnel barrier 52, the third tunnel barrier 54 and the fourth tunnel barrier 56 may include a single layer or multiple layers, for example two layers, three layers, four layers or any higher number of layers.

In addition, it should be appreciated that a plurality of the capping layer structure 20, the seed layer structure 22, the first spacer layer 40, the second spacer layer 42, the third spacer layer 44, the fourth spacer layer 46, the first tunnel barrier 50, the second tunnel barrier 52, the third tunnel barrier 54 and the fourth tunnel barrier 56, for example two, three, four or any higher number of each of the structure or layer, may be provided. As an example and not limitations, and using the capping layer structure 20 as an illustration, the plurality of the capping layer structure 20 may be arranged in a stack configuration. Correspondingly, any of the plurality of the structures or layers may be arranged in a stack configuration.

In the context of various embodiments of FIGS. 2A to 2C, 3A to 3C, 4, 5A to 5C, 6A to 6E and 7A to 7E, the respective magnetoresistive device 200, 210, 220, 300, 310, 320, 400, 500, 510, 520, 600, 610, 620, 630, 640, 700, 710, 720, 730, 740, may be a magnetic memory element. The respective magnetoresistive device 200, 210, 220, 300, 310, 320, 400, 500, 510, 520, may provide one, two, three, or four resistance states, which may enable data storage of one or more than one single bit of information, thereby allowing multi-state storage. The respective magnetoresistive device 600, 610, 620, 630, 640, 700, 710, 720, 730, 740, may provide one, two, three, four, five, six, seven or eight resistance states, which may enable data storage of one or more than one single bit of information, thereby allowing multi-state storage.

In the context of various embodiments, each of the at least one fixed magnetic layer structure or hard layer of a magnetoresistive device with GMR or TMR may include a material or a combination of materials selected from a group of materials consisting of cobalt (Co), palladium (Pd), platinum (Pt), cobalt-iron (CoFe), cobalt-iron-boron (CoFeB), iron-platinum (FePt), cobalt-platinum (CoPt), and cobalt-chromium-platinum (CoCrPt).

In the context of various embodiments, each of the at least two free magnetic layer structures or soft layers of a magnetoresistive device with GMR or TMR may include a material or a combination of materials selected from a group of materials consisting of cobalt (Co), palladium (Pd), platinum (Pt), cobalt-iron (CoFe), cobalt-iron-boron (CoFeB), iron-platinum (FePt), cobalt-platinum (CoPt), and cobalt-chromium-platinum (CoCrPt).

In the context of various embodiments, each of the at least one fixed magnetic layer structure and the at least two free magnetic layer structures include one or more materials with a perpendicular magnetic anisotropy.

In various embodiments, each of the at least one fixed magnetic layer structure and the at least two free magnetic layer structures may include alternating layers of cobalt (Co) and a material of either palladium (Pd) or platinum (Pt). In further embodiments, each of the at least one fixed magnetic layer structure and the at least two free magnetic layer structures may include alternating layers of cobalt-iron (CoFe) and a material of either palladium (Pd) or platinum (Pt). In yet further embodiments, each of the at least one fixed magnetic layer structure and the at least two free magnetic layer structures may include alternating layers of cobalt-iron-boron (CoFeB) and a material of either palladium (Pd) or platinum (Pt).

In various embodiments, the number of layers of one of Co, CoFe and CoFeB, and the corresponding number of layers of one of Pd and Pt may be in a range of between 1 to 10, for example a range of between 1 to 5, a range of between 3 to 5 or a range of between 3 to 10. In various embodiments, the thickness of each layer of Co, CoFe, CoFeB, Pd and Pt may be in a range of between about 0.3 nm (3 Å) to about 1.5 nm (15 Å), for example a range of between about 0.3 nm to about 1.0 nm, a range of between about 0.3 nm to about 0.6 nm or a range of between about 0.5 nm to about 1.5 nm.

In yet further embodiments, each of the at least one fixed magnetic layer structure and the at least two free magnetic layer structures may include one or more layers of iron-platinum (FePt), cobalt-platinum (CoPt), or cobalt-chromium-platinum (CoCrPt). In various embodiments, the number of layers of one of FePt, CoPt and CoCrPt may be in a range of between 1 to 10, for example a range of between 1 to 5, a range of between 3 to 5 or a range of between 3 to 10. In various embodiments, the thickness of each layer of FePt, CoPt and CoCrPt may be in a range of between about 2 nm (20 Å) to about 5 nm (50 Å), for example a range of between about 2 nm to about 3.5 nm or a range of between about 3 nm to about 5 nm.

The at least one fixed magnetic layer structure and the at least two free magnetic layer structures may include materials with different properties such as coercivity, in order to allow their magnetization orientation to be reversible at different external magnetic fields or different spin torque current values. In various embodiments, the spin torque switching current may be related to the anisotropy field, spin polarization, saturation magnetization and thickness of each of the at least one fixed magnetic layer structure and the at least two free magnetic layer structures.

In the context of various embodiments, each of the at least one seed layer structure of a magnetoresistive device with GMR or TMR may include a material selected from a group consisting of tantalum (Ta), palladium (Pd), copper (Cu), ruthenium (Ru), gold (Au), platinum (Pt), silver (Ag), nickel-chromium (NiCr), nickel-iron-chromium (NiFeCr), and any combinations thereof (e.g. each of the at least one seed layer may include one or more materials from the group of materials as described).

In the context of various embodiments, each of the at least one seed layer structure may have a thickness in a range of between about 0.5 nm to about 10 nm, e.g. a range of between about 2 nm to about 8 nm or a range of between about 4 nm to about 6 nm. It should be appreciated that the thickness of each of the at least one seed layer structure may depend on the material of each of the at least one seed layer structure.

In the context of various embodiments, each of the at least one capping layer structure of a magnetoresistive device with GMR or TMR may include a material or a combination of materials selected from a group of materials consisting of tantalum (Ta), palladium (Pd), copper (Cu), ruthenium (Ru), gold (Au), platinum (Pt), and an alloy including at least one of tantalum (Ta), palladium (Pd), copper (Cu), ruthenium (Ru), gold (Au), or platinum (Pt).

In the context of various embodiments, each of the at least one capping layer structure may have a thickness in a range of between about 0.5 nm to about 30 nm, e.g. a range of between about 5 nm to about 25 nm or a range of between about 10 nm to about 20 nm. It should be appreciated that the thickness of each of the at least one capping layer may depend on the material of each of the at least one capping layer. Furthermore, as the thickness of each of the at least one capping layer may not affect the performance of the magnetoresistive device, the thickness may also be more than 30 nm (e.g. about 35 nm, about 40 nm, or about 50 nm).

In the context of various embodiments, the insulating layer of a magnetoresistive device with GMR or TMR may include a material selected from a group consisting of alumina (AlOₓ), silicon oxide (SiOₓ), silicon nitride (SiN), magnesium oxide (MgO), and titanium oxide (TiOₓ). In the context of various embodiments, the insulating layer may have any thickness, depending on the process design and/or method.

In the context of various embodiments, each of the first electrode (e.g. top electrode) and the second electrode (e.g. bottom electrode) of a magnetoresistive device with GMR or TMR may include a conductive material. In various embodiments, each of the first electrode (e.g. top electrode) and the second electrode (e.g. bottom electrode) may include a material or a combination of materials selected from a group of materials consisting of copper (Cu), aluminium (Al), tantalum (Ta), nitrogen (N), and an alloy including at least one of copper (Cu), aluminium (Al), tantalum (Ta), or nitrogen (N).

In the context of various embodiments, each of the first electrode (e.g. top electrode) and the second electrode (e.g. bottom electrode) may have a thickness in a range of between about 50 nm to a few microns, e.g. a range of between about 50 nm to about 10 μm, a range of between about 200 nm to about 5 μm or a range of between about 500 nm to about 1 μm. However, it should be appreciated that each of the first electrode (e.g. top electrode) and the second electrode (e.g. bottom electrode) may have a thickness may have any thickness, such that the thickness may also be less than 50 nm (e.g. about 5 nm, about 10 nm, about 20 nm or about 40 nm) or more than 10 μm (e.g. about 15 μm, about 20 μm or about 30 μm).

In the context of various embodiments, each separation layer may include a material selected from a group of materials consisting of a conductive and non-magnetic material, a non-conductive and non-magnetic material, and an insulator material. In various embodiments, each of the separation layer may include a material selected from a group of materials consisting of copper (Cu), magnesium oxide (MgO), alumina (AlOₓ) and titanium oxide (TiOₓ). It should be appreciated that other non-magnetic material or other insulator material may be used.

In various embodiments, the separation layer of a magnetoresistive device with GMR may be Cu while the separation layer (e.g. a tunnel barrier) of a magnetoresistive device with TMR may be one of MgO, AlOₓ and TiOₓ.

In various embodiments, the thickness of each Cu separation layer or spacer layer may be in a range of between about 1 nm (10 Å) to about 5 nm (50 Å), for example a range of between about 1 nm to about 3 nm or a range of between about 2 nm to about 5 nm. In various embodiments, the thickness of each separation layer or spacer layer (e.g. a tunnel barrier) of one of MgO, AlOₓ and TiOₓ, may be in a range of between about 0.5 nm (5 Å) to about 3 nm (30 Å), for example a range of between about 0.5 nm to about 1.5 nm or a range of between about 1 nm to about 3 nm.

In the context of various embodiments, each spin filtering layer of a magnetoresistive device with GMR or TMR may include a material selected from a group of materials consisting of cobalt (Co), iron (Fe), and alloys containing at least one of cobalt (Co) or iron (Fe). Each spin filtering layer may be a magnetic layer. In various embodiments, the thickness of each spin filtering layer may be in a range of between about 0.2 nm (2 Å) to about 1 nm (10 Å), for example a range of between about 0.2 nm to about 0.5 nm or a range of between about 0.4 nm to about 1 nm.

In the context of various embodiments, each in-plane spin polarizer layer of a magnetoresistive device with GMR or TMR may include a material or a combination of materials selected from a group of materials consisting of cobalt (Co), iron (Fe), nickel (Ni), cobalt-iron-boron (CoFeB), cobalt-iron-zirconium (CoFeZr) and an alloy including at least one of cobalt (Co), iron (Fe) or nickel (Ni). In various embodiments, the thickness of each in-plane spin polarizer layer may be in a range of between about 1.5 nm (15 Å) to about 5 nm (50 Å), for example a range of between about 1.5 nm to about 3 nm or a range of between about 3 nm to about 5 nm.

In various embodiments, the thickness of each layer (e.g. the respective hard layer, soft layer, separation layer, spin filtering layer and in-plane spin polarizer layer) of a magnetic junction of a magnetoresistive device may be provided, designed and changed independently of each other. As an example and not limitation, each of the soft layers may be thicker or thinner than the hard layer, depending on the compositions.

In various embodiments, the critical current densities for switching the magnetization orientation of the soft layer from parallel (P) to anti-parallel (AP), J^{P→AP}, and from AP to P, J^{AP→P}, may be given by the following equations 1 and 2 respectively:

$$\begin{matrix}{J}^{P -> AP} \approx \frac{{AM}_{S} t}{p ξ ( θ ( 0 ) )} ( {H}_{k} - 4 π {M}_{S} ) , & ( Equation 1 ) \\ {J}^{AP -> P} \approx - \frac{{AM}_{S} t}{p ξ ( θ ( π ) )} ( {H}_{k} - 4 π {M}_{S} ) , & ( Equation 2 )\end{matrix}$$

where Mₛ, Hₖ and t are the saturation magnetization, the perpendicular anisotropy field and the thickness of the soft layer, respectively. θ is the angle of the magnetization orientation of the soft layer, relative to the magnetization orientation of the hard layer (i.e. θ=0° when the magnetization orientation of the soft layer is in a parallel direction and θ=180° or π when the magnetization orientation of the soft layer is in an anti-parallel direction). The coefficient, p, is the spin polarization, the coefficient, is the spin-torque efficiency factor, and the coefficient, ξ, is a numerical factor which may vary depending on the model used for the critical current densities.

In various embodiments, by using ferromagnetic layers with perpendicular magnetization orientation for each hard layer and each soft layer, the performance of magnetoresistive devices (e.g. memory cells, memory elements or memory devices) based on such structures may be improved in terms of stability and potential for spin transfer switched MRAM devices. In embodiments where the hard layer is positioned or disposed between two soft layers, such a configuration or arrangement may minimize the interaction (e.g. magnetostatic interaction) between the two soft layers. Therefore, various embodiments may provide an alternative approach to conventional approaches using anti-ferromagnetic exchange bias layers to define the hard layer (or reference layer). This makes the fabrication process of various embodiments easier and more controllable as the process may not require magnetic fields during the deposition process or magnetic field annealing after deposition. Furthermore, for memory devices below about 50 nm in size, the anti-ferromagnetic layer itself may become thermally unstable and makes the exchange bias inefficient due to a reduction in the grain size of the anti-ferromagnetic layer.

In various embodiments, switching of magnetization orientation in dual pseudo spin valve (D-PSV) or triple pseudo spin valve (T-PSV) by spin torque effect may enable multi-level MRAM. In contrast, switching magnetization by using an external field may not be suitable when the MRAM device becomes smaller as magnetic field MRAM is not scalable.

In various embodiments, a deposition process for producing the D-PSV or the T-PSV is as follows.

A substrate is provided, for example a bare wafer or a wafer (e.g. Si) with underlying transistor devices. A bottom electrode made of copper (Cu) and/or aluminium (Al), or a combination of Cu and/or Al with tantalum (Ta) or nitrogen (N) is deposited.

Three or more ferromagnetic layers (e.g. including at least one hard layer and at least two soft layers) are successively deposited, separated by a separation layer in between two ferromagnetic layers. The separation layer may be, for example, a Cu spacer or an insulating tunnel barrier of MgO.

Optionally, one or more spin-filtering layers and/or one or more in-plane spin polarizer layers may be deposited during the deposition process.

A capping layer structure consisting of layers of tantalum (Ta), palladium (Pd), copper (Cu), ruthenium (Ru), gold (Au) or platinum (Pt) may be deposited.

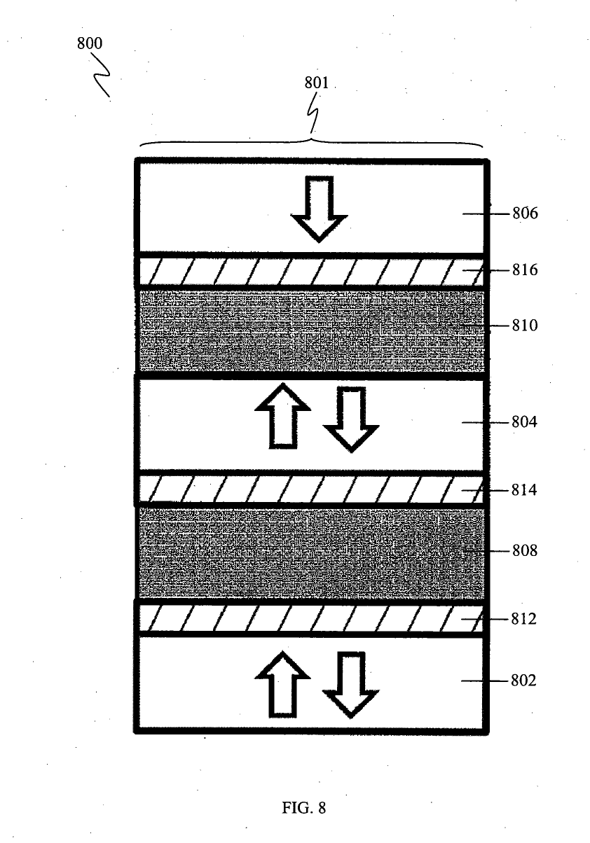

FIG. 8 shows a schematic cross-sectional diagram of a magnetoresistive device 800 having a magnetic junction 801 including spin filtering layers, according to various embodiments. The magnetoresistive device 800 may be a magnetic memory element. As an example and not limitations for demonstrating spin torque switching for a multi-level MRAM device with perpendicular anisotropy in accordance with various embodiments, the magnetic junction 801 includes a dual pseudo-spin valve (D-PSV).

The magnetic junction 801 with D-PSV includes a hard layer or a fixed magnetic layer structure 806 disposed over a first soft layer or first free magnetic layer structure 802 and a second soft layer or second free magnetic layer structure 804. Each of the hard layer 806, the first soft layer 802 and the second soft layer 804 may include alternating layers of Co and Pd. The hard layer 806 may include alternating layers of five layers of Co and five layers of Pd, with each layer of Pd having a thickness of about 8 angstrom (Å) and each layer of Co having a thickness of about 3 Å, such that the composition of the hard layer 806 may be represented as [Pd (8 Å)/Co (3 Å)]ₓ₅. The first soft layer 802 may include alternating layers of four layers of Co and four layers of Pd, with each layer of Pd having a thickness of about 6 Å and each layer of Co having a thickness of about 4 Å, such that the composition of the first soft layer 802 may be represented as [Co (4 Å)/Pd (6 Å)]ₓ₄. The second soft layer 804 may include alternating layers of three layers of Co and three layers of Pd, with each layer of Pd having a thickness of about 5 Å and each layer of Co having a thickness of about 5 Å, such that the composition of the second soft layer 804 may be represented as [Pd (5 Å)/Co (5 Å)]ₓ₃.

It should be appreciated that the number of alternating layers of Co and Pd and the thickness of each layer of Co and Pd may be changed, depending on the required parameters, for example coercivity, of each of the hard layer 806, the first soft layer 802 and the second soft layer 804.

In various embodiments, the respective coercivity of each of the hard layer 806, the first soft layer 802 and the second soft layer 804, may be in a range of between about 100 Oe (100 Oersted) to a few thousands Oersted, e.g. a range of between about 100 Oe to about 10000 Oe, a range of between about 500 Oe to about 8000 Oe, a range of between about 1000 Oe to about 5000 Oe or a range of between about 2000 Oe to about 4000 Oe.

The magnetic junction 801 further includes a first spacer layer 808 of Cu with a thickness of about 20 Å in between the first soft layer 802 and the second soft layer 804, a second spacer layer 810 of Cu with a thickness of about 20 Å in between the second soft layer 804 and the hard layer 806, a first spin filtering layer 812 of Co with a thickness of about 6 Å in between the first soft layer 802 and the first spacer layer 808, a second spin filtering layer 814 of Co with a thickness of about 8 Å in between the first spacer layer 808 and the second soft layer 804, and a third spin filtering layer 816 of Co with a thickness of about 6 Å in between the second soft layer 804 and the hard layer 806.

For the embodiment of FIG. 8, the first soft layer 802 having a multilayer stack configuration of [Co (4 Å)/Pd (6 Å)]ₓ₄ has a top layer of Co and a bottom layer of Pd. The top layer of Co is adjacent to a magnetic layer (e.g. which may be Co or other materials), which for the embodiment of FIG. 8 is the first spin filtering layer 812 of Co. In addition, the second soft layer 804 having a multilayer stack configuration of [Pd (5 Å)/Co (5 Å)]ₓ₃ has a top layer of Pd and a bottom layer of Co. The top layer of Pd is adjacent to the second spacer layer 810 of Cu while the bottom layer of Co is adjacent to the second spin filtering layer 814 of Co. Similarly, the hard layer 806 having a multilayer stack configuration of [Pd (8 Å)/Co (3 Å)]ₓ₅ has a top layer of Pd and a bottom layer of Co. The bottom layer of Co is adjacent to the third spin filtering layer 816 of Co.

For clarity purposes, other structures such as a seed layer structure, a capping layer structure, a top electrode and a bottom electrode are not shown in FIG. 8 but nevertheless are present for the magnetoresistive device 800. As an example and not limitations, a bottom electrode including laminated Cu and Ta bilayers may be provided.

Various magnetoresistive devices of different sizes may be fabricated by patterning the wafer. Measurements of the resistance as a function of magnetic field strength and also the resistance as a function of electrical current, may be subsequently performed.

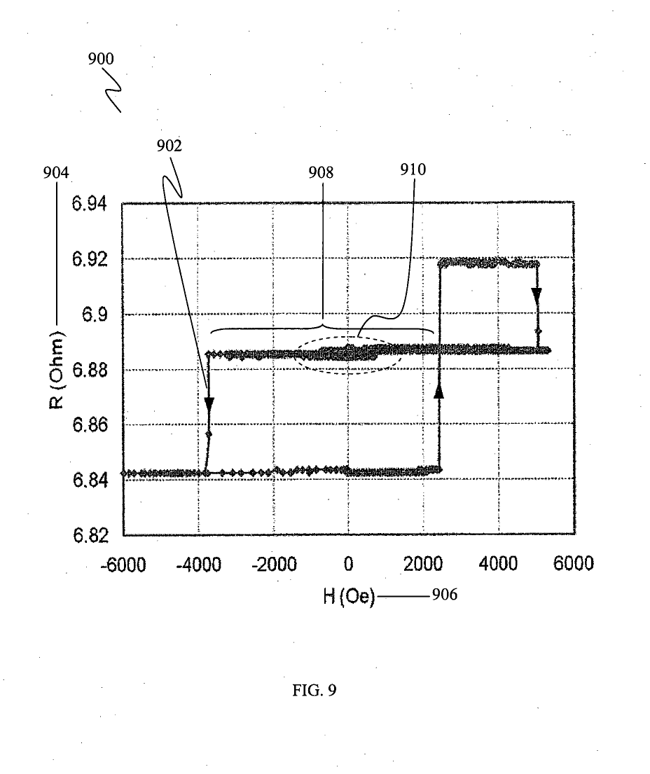

FIG. 9 shows a plot 900 illustrating a hysteresis loop 902 of a magnetoresistive device having a magnetic junction with D-PSV, according to various embodiments. The hysteresis loop 902 illustrates the resistance 904 as a function of magnetic field strength 906 of an applied external magnetic field, for a magnetoresistive device having about 150 nm diameter in terms of its lateral size, and with a magnetic junction having a similar arrangement as that of the embodiment of FIG. 8. For the purpose of the measurements to obtain the hysteresis loop 902, the current was fixed at approximately 75 μA.

As shown in FIG. 9, more than two states (e.g. resistance states) may be achieved using an external magnetic field. The magnetization of one of the ferromagnetically soft layer (storage layer) is reversed at about 2.5 kOe, while the magnetization of the other ferromagnetically soft layer (storage layer) is reversed at about 5 kOe. From FIG. 9, it may be observed that the magnetization of the ferromagnetically hard layer (reference layer) did not switch within the measurement range of up to about 6 kOe.

By measuring the minor loop 908, a small hysteresis loop, as represented within the dotted oval 910, may be observed. This may lead to two states, for example where further optimization of the spin filtering layer is carried out, for example by varying the material composition and/or thickness of the spin filtering layer.

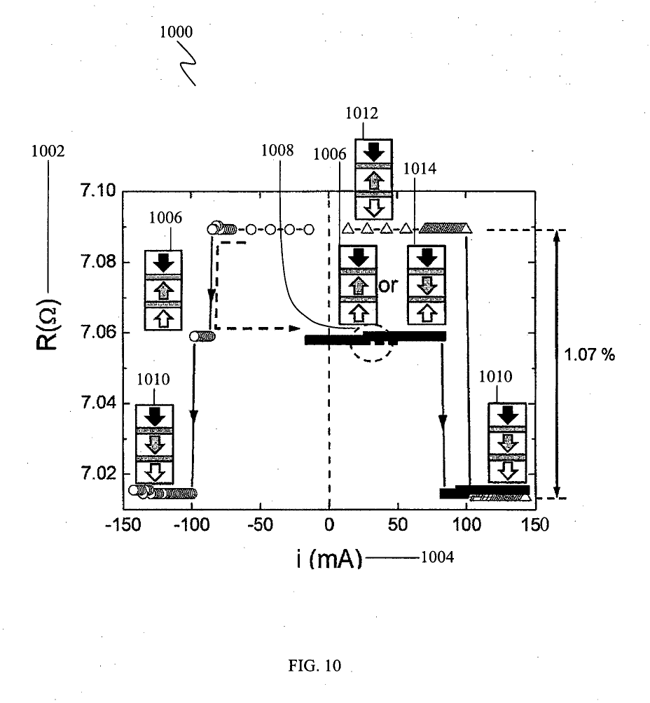

The device as used for the measurements shown in FIG. 9 was used to study the spin torque effect and the results are shown in FIG. 10. FIG. 10 shows a plot 1000 illustrating resistance 1002 as a function of electrical current 1004 of a magnetoresistive device having a magnetic junction with D-PSV, according to various embodiments. The electrical current 1004 may be applied as current pulses. As shown in FIG. 10, more than two states (e.g. resistance states) may be observed.

Starting from the intermediate state, as represented by 1006, a small hysteresis loop, as represented within the dotted circle 1008, may be observed, where further optimization of the magnetic junction may lead to four states (e.g. as represented by 1006, 1010, 1012, 1014) for the magnetoresistive device. In addition, as shown in FIG. 10, the difference between the highest resistance state and the lowest resistance state is approximately 1.07%.

While FIGS. 8 and 10 illustrate that the magnetization direction of the hard layer 806 is pointing in a downward direction, it should be appreciated that the magnetization direction may be in an upward direction, depending on user, design and application requirements. In other words, the magnetization direction of the hard layer 806 may be fixed, either in an upward or a downward direction.

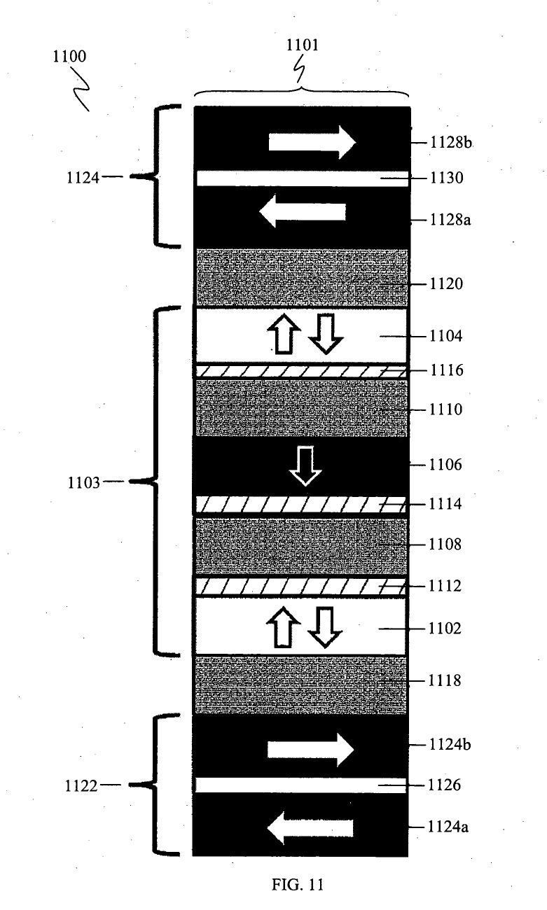

FIG. 11 shows a schematic cross-sectional diagram of a magnetoresistive device 1100 having a magnetic junction 1101 including antiferromagnetically coupled in-plane spin polarizer layers, e.g. a first antiferromagnetically coupled in-plane spin polarizer layer 1122 and a second antiferromagnetically coupled in-plane spin polarizer layer 1124, according to various embodiments. The magnetoresistive device 1100 may be a magnetic memory element. The first antiferromagnetically coupled in-plane spin polarizer layer 1122 and the second antiferromagnetically coupled in-plane spin polarizer layer 1124 are provided so that the switching current by spin torque effect may be reduced for the magnetoresistive device 1100.

The magnetic junction 1101 includes a giant magnetoresistive (GMR) dual pseudo-spin valve (D-PSV) 1103. The GMR-D-PSV 1103 includes a ferromagnetically hard layer or a fixed magnetic layer structure 1106 disposed between two ferromagnetically soft layers or free magnetic layer structures, e.g. a first ferromagnetically soft layer 1102 and a second ferromagnetically soft layer 1104. Such an arrangement may provide a clear difference between different resistance states in the magnetoresistive device 1100, as the interaction (e.g. magnetostatic interaction) between the first ferromagnetically soft layer 1102 and the second ferromagnetically soft layer 1104 may be minimized, as the ferromagnetically hard layer 1106 is disposed in between.

Each of the ferromagnetically hard layer 1106, the first ferromagnetically soft layer 1102 and the second ferromagnetically soft layer 1104 may include alternating layers of Co and Pd. The ferromagnetically hard layer 1106 may include alternating layers of six layers of Co and six layers of Pd, with each layer of Pd having a thickness of about 8 Å and each layer of Co having a thickness of about 3 Å, such that the composition of the ferromagnetically hard layer 1106 may be represented as [Pd (8 Å)/Co (3 Å)]ₛ₆. The first ferromagnetically soft layer 1102 may include alternating layers of two layers of Co and two layers of Pd, with each layer of Pd having a thickness of about 5 Å and each layer of Co having a thickness of about 5 Å, such that the composition of the first ferromagnetically soft layer 1102 may be represented as [Co (5 Å)/Pd (5 Å)]ₓ₂. The second ferromagnetically soft layer 1104 may include alternating layers of three layers of Co and three layers of Pd, with each layer of Pd having a thickness of about 5 Å and each layer of Co having a thickness of about 5 Å, such that the composition of the second ferromagnetically soft layer 1104 may be represented as [Pd (5 Å)/Co (5 Å)]ₓ₃.

It should be appreciated that the number of alternating layers of Co and Pd and the thickness of each layer of Co and Pd may be changed, depending on the required parameters, for example coercivity, of each of the ferromagnetically hard layer 1106, the first ferromagnetically soft layer 1102 and the second ferromagnetically soft layer 1104.

In various embodiments, the respective coercivity of each of the ferromagnetically hard layer 1106, the first ferromagnetically soft layer 1102 and the second ferromagnetically soft layer 1104 may be in a range of between about 100 Oe (100 Oersted) to a few thousands Oersted, e.g. a range of between about 100 Oe to about 10000 Oe, a range of between about 500 Oe to about 8000 Oe, a range of between about 1000 Oe to about 5000 Oe or a range of between about 2000 Oe to about 4000 Oe.

The GMR-D-PSV 1103 of the magnetic junction 1101 further includes a first spacer layer 1108 of Cu with a thickness of about 20 Å in between the ferromagnetically hard layer 1106 and the first ferromagnetically soft layer 1102, a second spacer layer 1110 of Cu with a thickness of about 20 Å in between the ferromagnetically hard layer 1106, the second ferromagnetically soft layer 1104, a first spin filtering layer 1112 of Co with a thickness of about 8 Å in between the first ferromagnetically soft layer 1102 and the first spacer layer 1108, a second spin filtering layer 1114 of Co with a thickness of about 8 Å in between the first spacer layer 1108 and the ferromagnetically hard layer 1106, and a third spin filtering layer 1116 of Co with a thickness of about 3 Å in between the second spacer layer 1110 and the second ferromagnetically soft layer 1104.

As shown in FIG. 11, the GMR-D-PSV 1103 is separated from each of the first antiferromagnetically coupled in-plane spin polarizer layer 1122 and the second antiferromagnetically coupled in-plane spin polarizer layer 1124 by a separation layer. The first ferromagnetically soft layer 1102 of the GMR-D-PSV 1103 is separated from the first antiferromagnetically coupled in-plane spin polarizer layer 1122 by a third spacer layer 1118 of Cu with a thickness of about 20 Å, while the second ferromagnetically soft layer 1104 of the GMR-D-PSV 1103 is separated from the second antiferromagnetically coupled in-plane spin polarizer layer 1124 by a fourth spacer layer 1120 of Cu with a thickness of about 20 Å.

Each of the first antiferromagnetically coupled in-plane spin polarizer layer 1122 and the second antiferromagnetically coupled in-plane spin polarizer layer 1124 is a synthetic antiferromagnetic structure with in-plane anisotropy. The first antiferromagnetically coupled in-plane spin polarizer layer 1122 includes two coupled in-plane spin polarizer layers 1124a, 1124b, with oppositely oriented magnetization directions, where each of the coupled in-plane spin polarizer layers 1124a, 1124b, is a layer of Co with a thickness of about 20 Å and is separated by a layer of Ru 1126 with a thickness of about 8 Å. Similarly, the second antiferromagnetically coupled in-plane spin polarizer layer 1124 includes two coupled in-plane spin polarizer layers 1128a, 1128b, with oppositely oriented magnetization directions, where each of the coupled in-plane spin polarizer layers 1128a, 1128b, is a layer of Co with a thickness of about 20 Å and is separated by a layer of Ru 1130 with a thickness of about 8 Å. In other words, each of the first antiferromagnetically coupled in-plane spin polarizer layer 1122 and the second antiferromagnetically coupled in-plane spin polarizer layer 1124 has a composition of Co (20 Å)/Ru (8 Å)/Co (20 Å).

For the embodiment of FIG. 11, the first ferromagnetically soft layer 1102 having a multilayer stack configuration of [Co (5 Å)/Pd (5 Å)]ₓ₂ has a top layer of Co and a bottom layer of Pd. The top layer of Co is adjacent to a magnetic layer (e.g. which may be Co or other materials), which for the embodiment of FIG. 11 is the first spin filtering layer 1112 of Co, while the bottom layer of Pd is adjacent to the third spacer layer 1118 of Cu. In addition, the second ferromagnetically soft layer 1104 having a multilayer stack configuration of [Pd (5 Å)/Co (5 Å)]ₓ₃ has a top layer of Pd and a bottom layer of Co. The top layer of Pd is adjacent to the fourth spacer layer 1120 of Cu while the bottom layer of Co is adjacent to the third spin filtering layer 1116 of Co. Similarly, the ferromagnetically hard layer 1106 having a multilayer stack configuration of [Pd (8 Å)/Co (3 Å)]ₓ₆ has a top layer of Pd and a bottom layer of Co. The top layer of Pd is adjacent to the second spacer layer 1110 of Cu while the bottom layer of Co is adjacent to the second spin filtering layer 1114 of Co.

For clarity purposes, other structures such as a seed layer structure, a capping layer structure, a top electrode and a bottom electrode are not shown in FIG. 11 but nevertheless are present for the magnetoresistive device 1100. As an example and not limitations, a bottom electrode including laminated Cu and Ta bilayers may be provided.

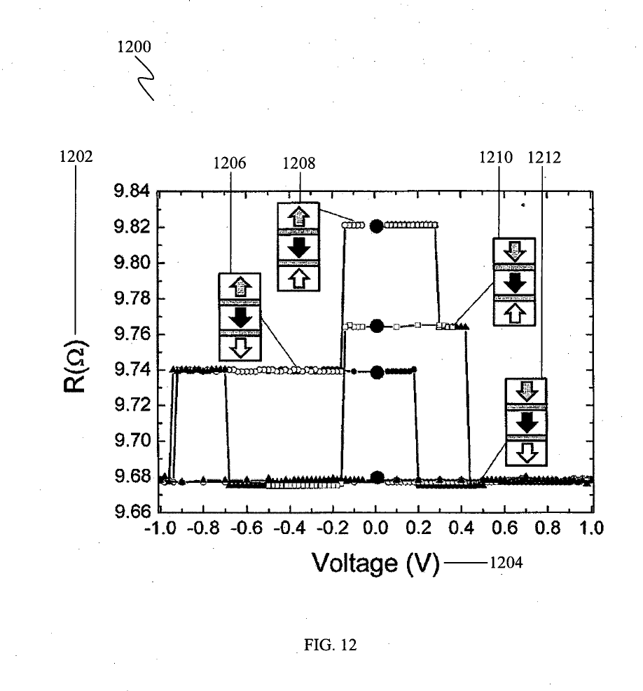

FIG. 12 shows a plot 1200 illustrating resistance 1202 as a function of voltage 1204 for the magnetoresistive device of the embodiment of FIG. 11. The voltage 1204 may be applied as voltage pulses. As shown in FIG. 12, four states (e.g. as represented by 1206, 1208, 1210, 1212) may be achieved using the spin torque effect. The four states (e.g. resistance states) 1206, 1208, 1210, 1212, are well separated and stable, and may be accessible as shown from the major and minor loops of the plot 1200. The four states 1206, 1208, 1210, 1212, are achieved as the magnetization of the ferromagnetically hard layer 1106, corresponding to the middle layer illustrated for the four states 1206, 1208, 1210, 1212, did not change during the measurement for FIG. 12, and only the magnetizations of the first ferromagnetically soft layer 1102 and the second ferromagnetically soft layer 1104, corresponding respectively to the bottom layer and the top layer for the four states 1206, 1208, 1210, 1212, switched under the spin torque effect.

In addition, as shown in FIG. 12, for the ferromagnetically hard layer with a predetermined magnetization orientation or direction, it may be possible to maintain the magnetization direction of either one of the two ferromagnetically soft layers while changing the magnetization direction of the other ferromagnetically soft layer.

Using FIG. 12 as an example and not limitations, based on the negative changing voltage, the magnetization direction of the top soft layer may first be oriented anti-parallel (i.e. pointing upwards) while the magnetization direction of the bottom soft layer may first be oriented parallel (i.e. pointing downwards), relative to the magnetization direction of the hard layer (i.e. pointing downwards). As the voltage (or current driven through the magnetic junction) changes, for example as the magnitude of the voltage decreases, the magnetization direction of the bottom soft layer may be changed accordingly to being anti-parallel.

In addition, based on the positive changing voltage, the magnetization direction of the top soft layer may first be oriented parallel (i.e. pointing downwards) while the magnetization direction of the bottom soft layer may first be oriented anti-parallel (i.e. pointing upwards), relative to the magnetization direction of the hard layer (i.e. pointing downwards). As the voltage (or current driven through the magnetic junction) changes, for example as the magnitude of the voltage increases, the magnetization direction of the bottom soft layer may be changed accordingly to being parallel.

In addition, as the polarity of the voltage 1204 changes from negative to positive, the magnetization direction of the top soft layer may be changed from being anti-parallel (i.e. pointing upwards) to being parallel (i.e. pointing downwards) as the magnitude of the voltage increases.

While FIGS. 11 and 12 illustrate that the magnetization direction of the ferromagnetically hard layer 1106 is pointing in a downward direction, it should be appreciated that the magnetization direction may be in an upward, direction, depending on user, design and application requirements. In other words, the magnetization direction of the ferromagnetically hard layer 1106 may be fixed, either in an upward or a downward direction.

The magnetoresistive device of the embodiments of FIGS. 11 and 12 may be used for a four-state spin torque MRAM memory (i.e. 2 bits/cell) which may double the storage density compared to a conventional spin-torque MRAM memory element.

Various embodiments may provide a writing scheme for the magnetoresistive device (e.g. a magnetic memory element) of various embodiments. Using four resistance states for the magnetoresistive device (e.g. a multi-level MRAM), as an example and not limitations, two bits may be stored using the four resistance states, where the four resistance states may be achieved by employing one or two voltage or current pulses. While using two pulses may appear to reduce the speed, the two bits may be written using two voltage or current pulses and hence the speed (e.g. the writing speed) may not be compromised.

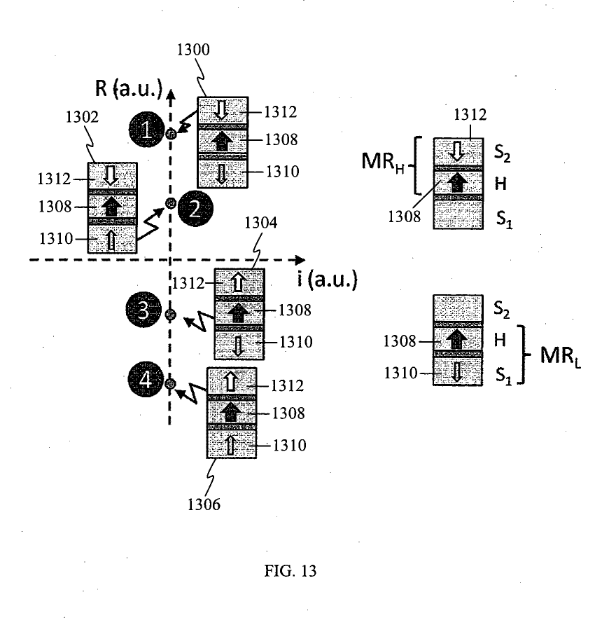

FIG. 13 shows a schematic diagram illustrating the four possible resistance states (e.g. resistance state (1) 1300, resistance state (2) 1302, resistance state (3) 1304, resistance state (4) 1306), for a magnetoresistive device having a magnetic junction, according to various embodiments. The magnetic junction includes a hard layer (H) 1308 disposed between a bottom soft layer (S₁) 1310 and a top soft layer (S₂) 1312. The magnetoresistive device may be a multi-level MRAM. For illustration purposes, the magnetization direction of the hard layer 1308 is shown pointing in an upward direction as the predetermined direction.

The resistance state (4) 1306, where the magnetization directions of the hard layer 1308, the bottom soft layer 1310 and the top soft layer 1312 are aligned parallel in one direction, shows the lowest resistance, while the resistance state (1) 1300, where the magnetization direction of the bottom soft layer 1310 and the top soft layer 1312 are aligned anti-parallel to the magnetization direction of the hard layer 1308, shows the highest resistance. As an example and not limitations, the hard layer 1308 and the top soft layer 1312 may be configured such that their anti-parallel states or alignment may provide a higher resistance than when the hard layer 1308 and the bottom soft layer 1310 are aligned anti-parallel (i.e. MR_{H}>MR_{L}). Accordingly, the resistance state (2) 1302 and the resistance state (3) 1304 may be provided, depending on the magnetization direction of the bottom soft layer 1310 and the top soft layer 1312. In various embodiments, even without prior knowledge of the existing resistance states of a magnetoresistive device (e.g. a magnetic memory element), it may be necessary to achieve or provide the resistance state (1) 1300, the resistance state (2) 1302, the resistance state (3) 1304 and the resistance state (4) 1306.

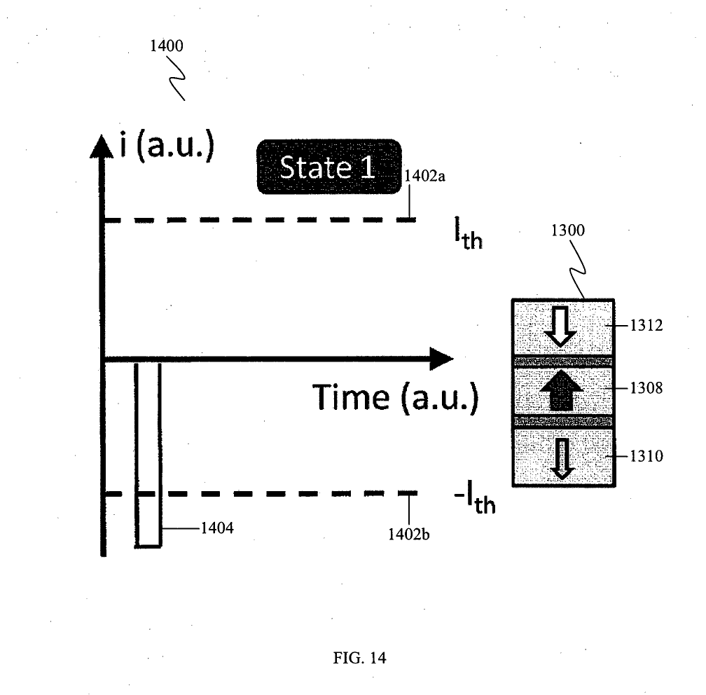

FIG. 14 shows a schematic diagram illustrating a writing scheme 1400 for achieving resistance state (1) 1300 of the embodiment of FIG. 13. A current pulse of a suitable magnitude may be applied to achieve resistance state (1) 1300.

The dotted lines 1402a, 1402b, show the threshold current Iₜₕ and −Iₜₕ respectively, beyond which the magnetization directions of the bottom soft layer 1310 and the top soft layer 1312 may be switched or reversed, while the magnetization direction of the hard layer 1308 may not be reversed. In other words, the threshold currents Iₜₕ 1402a and −Iₜₕ 1402b are less than the current level or magnitude needed to reverse the magnetization direction of the hard layer 1308, but are more than the current level needed to reverse the magnetization of the bottom soft layer 1310 and the top soft layer 1312. In addition, it should be appreciated that the current needed for switching the magnetization direction of the bottom soft layer 1310 may be less than any one of the threshold currents Iₜₕ 1402a and −Iₜₕ 1402b.

As shown in FIG. 14, a single current pulse 1404 with a negative polarity (i.e. in the negative direction) and having a suitable magnitude exceeding the threshold current −Iₜₕ 1402b may be applied to align the magnetization directions of the bottom soft layer 1310 and the top soft layer 1312 anti-parallel to the magnetization directions of the hard layer 1308, in order to achieve resistance state (1) 1300. The current pulse 1404 may have a pulse width depending on the design of the magnetoresistive device (e.g. an MRAM structure) and/or the applications, for example a pulse width of between about 0.2 ns to about 50 ns for applications in between about 20 MHz to about 5 GHz.

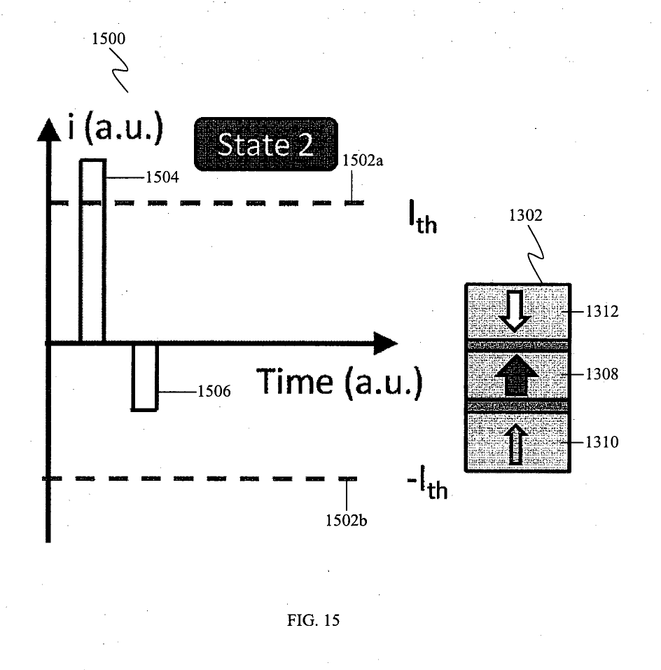

FIG. 15 shows a schematic diagram illustrating a writing scheme 1500 for achieving resistance state (2) 1302 of the embodiment of FIG. 13. Two current pulses of respectively suitable magnitude may be applied to achieve resistance state (2) 1302. The descriptions relating to the threshold currents Iₜₕ 1402a and −Iₜₕ 1402b of FIG. 14 may similarly be applicable to the threshold currents Iₜₕ 1502a and −Iₜₕ 1502b respectively.

For the writing scheme 1500, a current pulse 1504 with a positive polarity (i.e. in the positive direction, and in the opposite direction to the current pulse 1404 of FIG. 14 for achieving resistance state (1) 1300) and having a suitable magnitude exceeding the threshold current Iₜₕ 1502a may be applied to first align the magnetization directions of the bottom soft layer 1310 and the top soft layer 1312 parallel to the magnetization direction of the hard layer 1308. The magnitude of the current pulse 1504 does not have a switching effect on the hard layer 1308.

Subsequently, another current pulse 1506 with a negative polarity (i.e. in the negative direction and in the opposite direction to the current pulse 1504) and having a suitable magnitude, which may be smaller or less than the threshold current −Iₜₕ 1502b, may be applied to switch the magnetization direction of the top soft layer 1312 to being anti-parallel to the magnetization direction of the hard layer 1308, in order to achieve resistance state (2) 1302. Each of the current pulses 1504, 1506, may have a pulse width depending on the design of the magnetoresistive device (e.g. an MRAM structure) and/or the applications, for example a pulse width of between about 0.2 ns to about 50 ns for applications in between about 20 MHz to about 5 GHz.

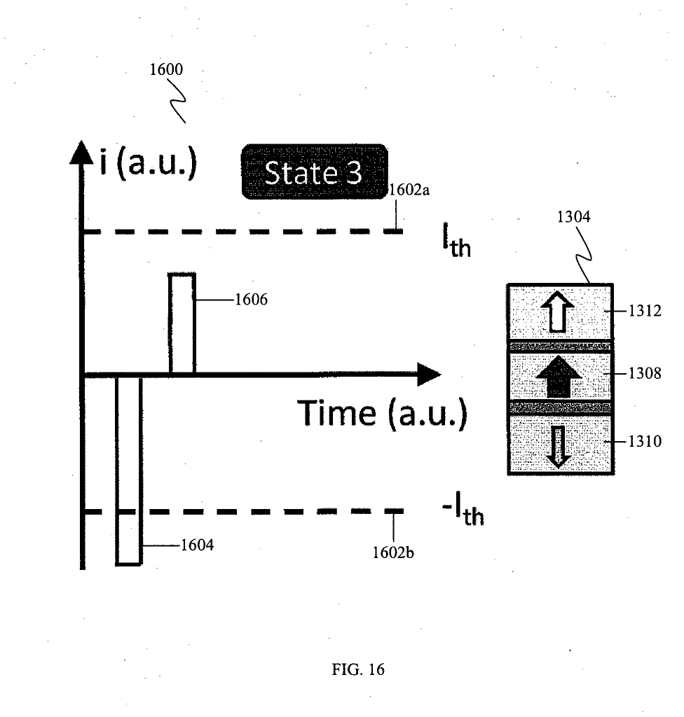

FIG. 16 shows a schematic diagram illustrating a writing scheme 1600 for achieving resistance state (3) 1304 of the embodiment of FIG. 13. Two current pulses of respectively suitable magnitude may be applied to achieve resistance state (3) 1304. The descriptions relating to the threshold currents Iₜₕ 1402a and −Iₜₕ 1402b of FIG. 14 may similarly be applicable to the threshold currents Iₜₕ 1602a and −Iₜₕ 1602b respectively.

For the writing scheme 1600, a current pulse 1604 with a negative polarity (i.e. in the negative direction, and in the opposite direction to the current pulse 1504 of FIG. 15 for achieving resistance state (2) 1302) and having a suitable magnitude exceeding the threshold current −Iₜₕ 1602b may be applied to first align the magnetization directions of the bottom soft layer 1310 and the top soft layer 1312 anti-parallel to the magnetization direction of the hard layer 1308. The magnitude of the current pulse 1604 does not have a switching effect on the hard layer 1308.

Subsequently, another current pulse 1606 with a positive polarity (i.e. in the positive direction and in the opposite direction to the current pulse 1604) and having a suitable magnitude, which may be smaller or less than the threshold current Iₜₕ 1602a, may be applied to switch the magnetization direction of the top soft layer 1312 to being parallel to the magnetization direction of the hard layer 1308, in order to achieve resistance state (3) 1304. Each of the current pulses 1604, 1606, may have a pulse width depending on the design of the magnetoresistive device (e.g. an MRAM structure) and/or the applications, for example a pulse width of between about 0.2 ns to about 50 ns for applications in between about 20 MHz to about 5 GHz.

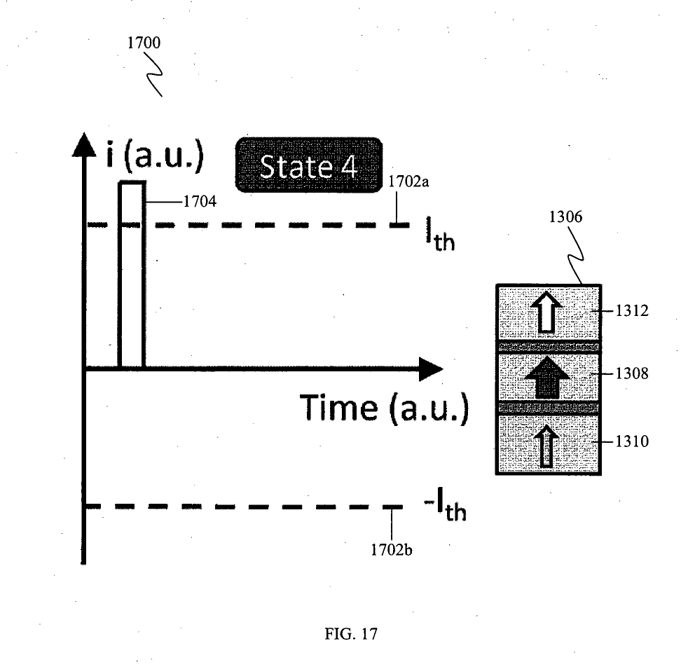

FIG. 17 shows a schematic diagram illustrating a writing scheme 1700 for achieving resistance state (4) 1306 of the embodiment of FIG. 13. A current pulse of a suitable magnitude may be applied to achieve resistance state (4) 1306. The descriptions relating to the threshold currents Iₜₕ 1402a and −Iₜₕ 1402b of FIG. 14 may similarly be applicable to the threshold currents Iₜₕ 1702a and −Iₜₕ 1702b respectively.

As shown in FIG. 17, a single current pulse 1704 with a positive polarity (i.e. in the positive direction) and having a suitable magnitude exceeding the threshold current Iₜₕ 1702a may be applied to align the magnetization directions of the bottom soft layer 1310 and the top soft layer 1312 parallel to the magnetization directions of the hard layer 1308, in order to achieve resistance state (4) 1306. The current pulse 1704 may have a pulse width depending on the design of the magnetoresistive device (e.g. an MRAM structure) and/or the applications, for example a pulse width of between about 0.2 ns to about 50 ns for applications in between about 20 MHz to about 5 GHz.

It should be appreciated that while one or two current pulses are employed for the writing schemes 1400, 1500, 1600, 1700, respectively of FIGS. 14, 15, 16, 17, alternatively, one or more voltage pulses may be employed. Accordingly, the dotted lines shown in FIGS. 14, 15, 16, 17, for the respective current thresholds Iₜₕ and −Iₜₕ, may refer to voltage thresholds Vₜₕ and −Vₜₕ, respectively.

In addition, various embodiments may provide a writing scheme for the magnetoresistive device (e.g. a magnetic memory element) of various embodiments, where for example, coding techniques may be used to minimize the writing currents of resistance state (2) 1302 and resistance state (3) 1304. This improves the writing speed and also minimizes the requirements to achieve multi-level or the associated errors. For this writing scheme, a resistance state may be read first, so that the magnetization configuration or orientation may be recognized. Then, a current pulse or a voltage pulse with an adjustable amplitude and direction (e.g. polarity) may be applied to reverse or switch the magnetization orientation of either one of the two soft layers to reach the desired resistance state.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

### LIST OF REFERENCE NUMBERS FOR FIGS. 2A TO 2C, 3A TO 3C, 4, 5A TO 5C, 6A TO 6E, 7A TO 7E AND 8

200, 210, 220, 300, 310, 320, 400, 500, 510, 520, 600, 610, 620, 630, 640, 700, 710, 720, 730, 740, 800 Magnetoresistive device
10 Top electrode
12 Bottom electrode
14a First insulator
14b Second insulator
20 Capping layer structure
22 Seed layer structure
24a, 24b, 24c, 25a, 25b, 25c, 26, 27a, 27b, 27c, 28a, 28b, 28c, 28d, 28e, 29a, 29b, 29c, 29d, 29e, 801 Magnetic junction
30, 802 First soft layer (First free magnetic layer structure)
32, 804 Second soft layer (Second free magnetic layer structure)
33 Third soft layer (Third free magnetic layer structure)
34, 806 Hard layer, First hard layer (Fixed magnetic layer structure, First fixed magnetic layer structure)
36 Second hard layer (Second fixed magnetic layer structure)
40, 808 First spacer layer
42, 810 Second spacer layer
44 Third spacer layer
46 Fourth spacer layer
50 First tunnel barrier
52 Second tunnel barrier
54 Third tunnel barrier
56 Fourth tunnel barrier
60, 812 First spin filtering layer
62, 814 Second spin filtering layer
64, 816 Third spin filtering layer
66 Fourth spin filtering layer
70 In-plane spin polarizer layer, First in-plane spin polarizer layer
72 Second in-plane spin polarizer layer

1. A magnetoresistive device having a magnetic junction, the magnetic junction comprising:
at least one fixed magnetic layer structure having a fixed magnetization orientation; and
at least two free magnetic layer structures, each of the at least two free magnetic layer structures having a variable magnetization orientation;
wherein the at least one fixed magnetic layer structure overlaps with the at least two free magnetic layer structures such that a current flow is possible through the magnetic junction; and
wherein the at least one fixed magnetic layer structure and the at least two free magnetic layer structures are respectively configured such that the fixed magnetization orientation and the variable magnetization orientation are oriented in a direction substantially perpendicular to a plane defined by an interface between the at least one fixed magnetic layer structure and either one of the at least two free magnetic layer structures.

2. The magnetoresistive device of claim 1, wherein each of the at least two free magnetic layer structures is configured such that the variable magnetization orientation of each of the at least two free magnetic layer structures varies relative to the current applied through the magnetic junction.

3-6. (canceled)

7. The magnetoresistive device of claim 1, further comprising at least one seed layer structure, wherein the magnetic junction is disposed over the at least one seed layer structure.

8. (canceled)

9. The magnetoresistive device of claim 1, further comprising at least one capping layer structure, wherein the at least one capping layer structure is disposed over the magnetic junction.

10-11. (canceled)

12. The magnetoresistive device of claim 1, further comprising an insulator layer configured to surround the magnetic junction.

13. (canceled)

14. The magnetoresistive device of claim 1, further comprising a first electrode disposed at one side of the magnetic junction.

15-16. (canceled)

17. The magnetoresistive device of claim 14, further comprising a second electrode disposed at an opposite side of the magnetic junction.

18-20. (canceled)

21. The magnetoresistive device of claim 1, wherein the magnetic junction further comprises at least one first separation layer disposed between the at least one fixed magnetic layer structure and either one of the at least two free magnetic layer structures.

22-23. (canceled)

24. The magnetoresistive device of claim 21, wherein the magnetic junction further comprises at least one first spin filtering layer disposed between the at least one fixed magnetic layer structure and the at least one first separation layer.

25. The magnetoresistive device of claim 24, wherein the at least one first spin filtering layer comprises a material selected from a group of materials consisting of cobalt, iron, and alloys containing at least one of cobalt or iron.

26. The magnetoresistive device of claim 21, wherein the magnetic junction further comprises at least one second spin filtering layer disposed between either one of the at least two free magnetic layer structures and the at least one first separation layer.

27. The magnetoresistive device of claim 26, wherein the at least one second spin filtering layer comprises a material selected from a group of materials consisting of cobalt, iron, and alloys containing at least one of cobalt or iron.

28. The magnetoresistive device of claim 21, wherein the magnetic junction further comprises at least one second separation layer disposed between each of the at least two free magnetic layer structures.

29-31. (canceled)

32. The magnetoresistive device of claim 28, wherein the magnetic junction further comprises at least one third spin filtering layer disposed between either one of the at least two free magnetic layer structures and the at least one second separation layer.

33. (canceled)

34. The magnetoresistive device of claim 1, wherein the magnetic junction further comprises at least one in-plane spin polarizer layer disposed adjacent to at least either one or both of the at least two free magnetic layer structures.

35. The magnetoresistive device of claim 34, wherein the at least one in-plane spin polarizer layer comprises a magnetization orientation in a direction substantially parallel to the plane defined by the interface between the at least one fixed magnetic layer structure and either one of the at least two free magnetic layer structures.

36. The magnetoresistive device of claim 34, wherein the at least one in-plane spin polarizer layer comprises a material or a combination of materials selected from a group of materials consisting of cobalt, iron, nickel, cobalt-iron-boron (CoFeB), cobalt-iron-zirconium (CoFeZr) and an alloy including at least one of cobalt, iron or nickel.

37. The magnetoresistive device of claim 1, wherein the at least one fixed magnetic layer structure comprises a coercivity larger than each of the at least two free magnetic layer structures.

38-41. (canceled)

42. The magnetoresistive device of claim 1, wherein the at least one fixed magnetic layer structure comprises a material or a combination of materials selected from a group of materials consisting of cobalt, palladium, platinum, cobalt-iron, cobalt-iron-boron, iron-platinum, cobalt-platinum, and cobalt-chromium-platinum.

43. The magnetoresistive device of claim 1, wherein each of the at least two free magnetic layer structures comprises a material or a combination of materials selected from a group of materials consisting of cobalt, palladium, platinum, cobalt-iron, cobalt-iron-boron, iron-platinum, cobalt-platinum, and cobalt-chromium-platinum.
